(19) United States
(12) Patent Application Publication
(10) Pub. No.: US 2024/0196697 A1
(43) Pub. Date: Jun. 13, 2024

(54) Light Emitting Display Device

(71) Applicant: LG Display Co., Ltd., Seoul (KR)

(72) Inventor: Choonghyo Kim, Paju-si (KR)

(21) Appl. No.: 18/474,621

(22) Filed: Sep. 26, 2023

(30) Foreign Application Priority Data
Dec. 12, 2022 (KR) 10-2022-0172596

(51) Int. Cl. H10K 59/80; H10K 59/12; H10K 59/124

(52) U.S. Cl. CPC H10K 59/80522; H10K 59/1201; H10K 59/124

(57) ABSTRACT

A light emitting display device includes an auxiliary power electrode disposed on a substrate, at least one dummy electrode disposed at a periphery of the auxiliary power electrode, on the substrate, at least one protection layer covering the auxiliary power electrode and the at least one dummy electrode, and a contact portion passing through the at least one protection layer to expose a portion of the auxiliary power electrode, wherein the at least one dummy electrode is electrically floated, or is supplied with the same voltage as a voltage applied to the auxiliary power electrode.

### CROSS-REFERENCE TO RELATED APPLICATIONS

This application claims the benefit of Republic of Korea Patent Application No. 10-2022-0172596 filed on Dec. 12, 2022, which is hereby incorporated by reference in its entirety.

### BACKGROUND

### Technical Field

The present disclosure relates to a light emitting display device.

### Discussion of the Related Art

With the advancement of an information-oriented society, attentions and requirements for a display device configured to display an image have been increased in various types. Accordingly, a display device such as a Liquid Crystal Display (LCD), an organic light emitting display (OLED), a Micro Light Emitting Diode (Micro LED), a quantum dot display device (QD), or the like is utilized.

Among these display devices, the light emitting display device is classified into an inorganic light emitting display device and an organic light emitting display device depending on a material of a light emitting layer. For example, the organic light emitting display device is self-luminous, wherein holes and electrons are injected into an emission layer from an anode electrode for a hole injection and a cathode electrode for an electron injection, and light is emitted when excitons in which the injected holes and electrons are combined fall from an excited state to a ground state, to thereby display an image.

The light emitting display device may be divided into a top emission type, a bottom emission type, or a dual emission type according to a direction in which light is emitted.

In case of the light emitting display device of the top emission type, a transparent electrode or a semi-transmissive electrode may be used as a cathode to emit light from the light emitting layer to an upper portion. The cathode electrode has a thin profile (or thickness) to improve transmittance, thereby increasing an electrical resistance. Particularly, in case of the large-sized light emitting display device, a voltage drop may be more severely generated as a distance from a voltage supplying pad increases, whereby a luminance non-uniformity problem of the light emitting display device might occur.

The above content of the background technology may be retained for a deduction of the present disclosure by inventors or may be technology information learned by practice of embodiments of the present disclosure. However, the above content of the background technology may not be a prior art published to the general public before an application of the present disclosure.

### SUMMARY

To solve a problem where voltage drop occurs due to an increase in resistance of a cathode electrode in a light emitting display device, a method is being proposed where an undercut region, enabling an auxiliary electrode supplying an auxiliary power to be electrically connected with the cathode electrode, is formed and voltage drop is reduced by supplying the auxiliary power to the cathode electrode.

However, when an electrical connection between the cathode electrode and the auxiliary electrode is not smooth in the undercut region, a repair process such as laser welding is needed for recovering the electrical connection between the cathode electrode and the auxiliary electrode, but it is difficult to secure a margin for performing the repair process and it is difficult to apply the repair process due to damage applied to an undercut structure configuring an undercut region.

An aspect of the present disclosure is directed to providing a light emitting display device which has a repair structure for a contact defect of a cathode contact region.

Another aspect of the present disclosure is directed to providing a light emitting display device which may repair a contact defect of a cathode contact region while securing the structural stability of an undercut structure.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these and other advantages and in accordance with the purpose of the disclosure, as embodied and broadly described herein, there is provided a light emitting display device including an auxiliary power electrode disposed on a substrate, at least one dummy electrode disposed at a periphery of the auxiliary power electrode, on the substrate, at least one protection layer covering the auxiliary power electrode and the at least one dummy electrode, and a contact portion passing through the at least one protection layer to expose a portion of the auxiliary power electrode, wherein the at least one dummy electrode is electrically floating, or is supplied with a same voltage as a voltage applied to the auxiliary power electrode.

A light emitting display device according to the present disclosure may have a repair structure which may repair a contact defect of a cathode contact region while securing the structural stability of an undercut structure.

According to the present disclosure, a yield rate of a light emitting display device may be enhanced through recycling based on defect repair in a manufacturing process of the light emitting display device, thereby reducing the manufacturing cost and enhancing productivity and reliability.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a block diagram schematically illustrating a light emitting display device according to an embodiment of the present disclosure;

FIG. 2 is a diagram schematically illustrating a first electrode, an auxiliary power line, a bank layer, and a contact portion of each subpixel in a light emitting display device according to an embodiment of the present disclosure;

FIG. 3 is a diagram taken along line I-I′ of FIG. 2 in a light emitting display device according to an embodiment of the present disclosure;

FIG. 4 is a plan view illustrating a contact portion illustrated in a region A of FIG. 3 according to an embodiment of the present disclosure;

FIG. 5 is a cross-sectional view taken along line II-II′ of FIG. 4 according to an embodiment of the present disclosure;

FIG. 6 is a cross-sectional view taken along line III-III′ of FIG. 4 according to an embodiment of the present disclosure;

FIGS. 7 and 8 are diagrams for describing a contact defect occurring in a contact portion according to an embodiment of the present disclosure and a process of repairing the contact defect;

FIG. 9 is a plan view illustrating a contact portion illustrated in a region A of FIG. 3 according to another embodiment of the present disclosure;

FIG. 10 is a cross-sectional view taken along line IV-IV′ of FIG. 9;

FIG. 11 is a plan view illustrating a contact portion illustrated in a region A of FIG. 3 according to another embodiment of the present disclosure;

FIG. 12 is a cross-sectional view taken along line V-V′ of FIG. 11 according to an embodiment of the present disclosure;

FIG. 13 is another cross-sectional view taken along line V-V′ of FIG. 11 according to an embodiment of the present disclosure; and

FIGS. 14 to 23 are manufacturing process diagrams for describing a method of manufacturing a light emitting display device according to an embodiment of the present disclosure.

### DETAILED DESCRIPTION OF THE DISCLOSURE

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜’, ‘above˜’, ‘below˜’, and ‘next to˜’, one or more portions may be arranged between two other portions unless ‘just’ or ‘direct’ is used.

In describing a temporal relationship, for example, when the temporal order is described as “after,” “subsequent,” “next,” and “before,” a case which is not continuous may be included, unless “just” or “direct” is used.

It will be understood that, although the terms “first”, “second”, etc., may be used herein to describe various elements, these elements should not be limited by these terms. These terms are only used to partition one element from another. For example, a first element could be termed a second element, and, similarly, a second element could be termed a first element, without departing from the scope of the present disclosure.

The terms “first horizontal axis direction,” “second horizontal axis direction,” and “vertical axis direction” should not be interpreted only based on a geometrical relationship in which the respective directions are perpendicular to each other, and may be meant as directions having wider directivities within the range within which the components of the present disclosure can operate functionally.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, a preferred embodiment of a light emitting display device according to the present disclosure will be described in detail with reference to the accompanying drawings. Wherever possible, the same reference numbers will be used throughout the drawings to refer to the same or like parts. Since a scale of each of elements shown in the accompanying drawings is different from an actual scale for convenience of description, the present disclosure is not limited to the shown scale.

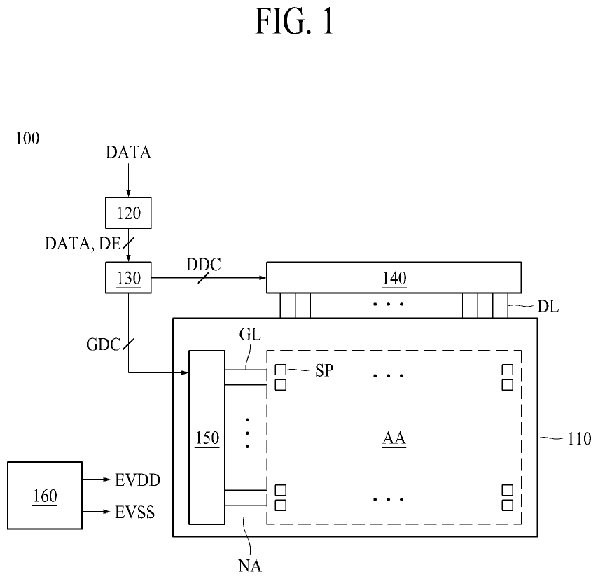

FIG. 1 is a block diagram schematically illustrating a light emitting display device according to one embodiment of the present disclosure.

Referring to FIG. 1, the light emitting display device 100 according to one embodiment of the present disclosure may include a display panel 110, an image processor 120, a timing controller 130, a data driver 140, a scan driver 150, and a power supply portion 160.

The display panel 110 may display an image corresponding to a data signal DATA supplied from the data driver 140, a scan signal supplied from the scan driver 150, and power supplied from the power supply portion 160.

The display panel 110 may include a sub pixel SP disposed at every intersection of a plurality of gate lines GL and a plurality of data lines DL. A structure of the sub pixel SP may vary depending on the type of the display device 100.

For example, the sub pixels SP may be formed in a top emission method, a bottom emission method, or a dual emission method according to the structure. The sub pixels SP refer to unit capable of emitting light of their own color with or without a specific type of color filter. The sub pixels SP may include a red sub pixel, a green sub pixel, and a blue sub pixel. Alternatively, the sub pixel SP may include a red sub pixel, a blue sub pixel, a white sub pixel, and a green sub pixel. The sub pixels SP may have one or more other light emitting areas according to light emitting characteristics.

The one or more sub pixels SP may constitute one unit pixel. For example, one unit pixel may include red, green, and blue sub pixels, and the red, green, and blue sub pixels may be repeatedly arranged. Alternatively, one unit pixel may include red, green, blue, and white subpixels, wherein the red, green, blue and white subpixels may be repeatedly arranged, or the red, green, blue and white subpixels may be arranged in a quad type. In the embodiment according to the present disclosure, the color type, arrangement type, arrangement order, etc., of the sub pixels may be configured in various forms depending on the luminous characteristics, the lifespan of the device, the spec of the device, and the like, whereby it is not limited thereto.

The display panel 110 may be divided into a display area AA for displaying an image by arranging the sub pixels SP, and a non-display area NA around the display area AA. The scan driver 150 may be provided on the non-display area NA of the display panel 110. In addition, the non-display area NA may include a pad area.

The image processor 120 may output a data enable signal DE together with the data signal DATA supplied from the outside. The image processor 120 may output one or more of a vertical synchronization signal, a horizontal synchronization signal, and a clock signal in addition to the data enable signal DE.

The timing controller 130 may receive the data signal DATA as well as a driving signal from the image processor 120. The driving signal may include the data enable signal DE. Alternatively, the driving signal may include a vertical synchronization signal, a horizontal synchronization signal, and a clock signal. The timing controller 130 may output a data timing control signal DDC for controlling the operation timing of the data driver 140, and a gate timing control signal GDC for controlling the operation timing of the scan driver 150 based on the driving signal.

The data driver 140 may convert the data signal DATA into a gamma reference voltage by sampling and latching the data signal DATA supplied from the timing controller 130 in response to the data timing control signal DDC supplied from the timing controller 130, and may output the gamma reference voltage.

The data driver 140 may output the data signal DATA through the data lines DL. The data driver 140 may be implemented in the form of an integrated circuit IC. For example, the data driver 140 may be electrically connected to the pad area disposed in the non-display area NA of the display panel 110 through a flexible circuit film.

The scan driver 150 may output the scan signal in response to the gate timing control signal GDC supplied from the timing controller 130. The scan driver 150 may output the scan signal through the gate lines GL. The scan driver 150 may be implemented in the form of an integrated circuit IC or may be implemented in a gate-in-panel GIP scheme.

The power supply portion 160 may output a high potential voltage and a low potential voltage for driving the display panel 110. The power supply portion 160 may supply the high potential voltage to the display panel 110 through a first power line EVDD (driving power line or pixel power line), and may supply the low potential voltage to the display panel 110 through a second power line EVSS (auxiliary power line or common power line).

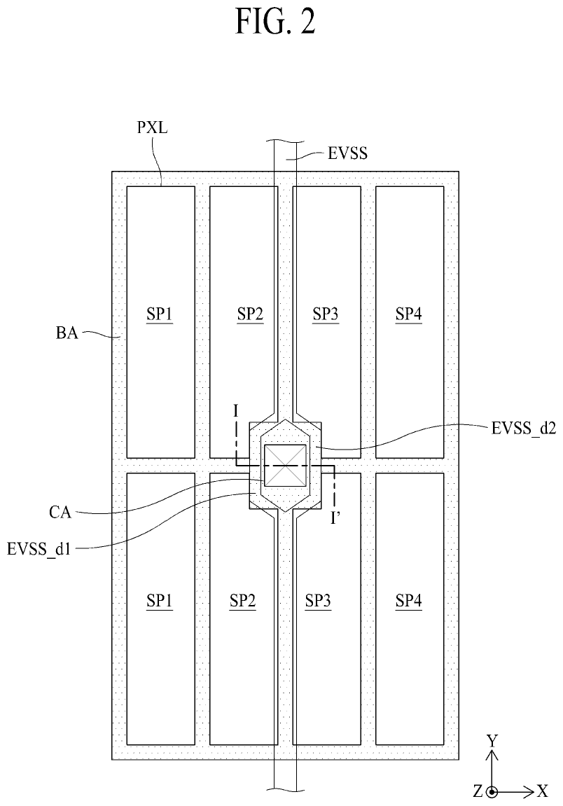

FIG. 2 is a plan view schematically illustrating a first electrode, an auxiliary power line, a bank layer, and a contact portion of sub pixels in the light emitting display device according to the embodiment of the present disclosure.

Referring to FIG. 2 in connection with FIG. 1, the display panel 110 of the light emitting display device 100 according to the embodiment of the present disclosure may be divided into the display area AA and the non-display area NA, and may include the plurality of sub pixels SP1, SP2, SP3, and SP4 defined by the intersection between the gate line GL and the data line DL on the substrate of the display area AA.

Referring to FIG. 2, the plurality of sub pixels SP1, SP2, SP3, and SP4 may include the first sub pixel SP1, the second sub pixel SP2, the third sub pixel SP3, and the fourth sub pixel SP4. For example, the first sub pixel SP1 may emit red light, the second sub pixel SP2 may emit green light, the third sub pixel SP3 may emit blue light, and the fourth sub pixel SP4 may emit white light, but not necessarily. It is possible to omit the fourth sub pixel SP4 for emitting white light. It is possible to configure the sub pixels emitting at least two of red light, green light, blue light, yellow light, magenta light, and cyan light. Also, the arrangement order of the sub pixels SP1, SP2, SP3, and SP4 may be variously changed.

A pixel electrode PXL (or anode electrode or first electrode) may be disposed in each of the plurality of sub pixels SP1, SP2, SP3, and SP4. A bank layer BA covering (or overlaying) an edge portion of the pixel electrode PXL and defining an opening corresponding to the plurality of sub pixels SP1, SP2, SP3, and SP4 may be disposed on the pixel electrode PXL. Then, a light emitting layer (or organic light emitting layer) and a common electrode (or cathode electrode or second electrode) may be sequentially stacked on the pixel electrode PXL and the bank layer BA.

According to an embodiment of the present disclosure, in order to decrease a resistance of a common electrode formed all over an entire surface of a display panel 110 (the common electrode may be formed all over the display area AA and may extend to the non-display area NA, including covering the auxiliary power line in the non-display area NA), an auxiliary power electrode which includes a material having a lower resistance than that of the common electrode and is electrically connected with the common electrode in contact with the common electrode and an auxiliary power line EVSS (a common power line or a second power line) transferring an auxiliary power (or a low level voltage) to the auxiliary power electrode may be provided. The bank layer BA may define a contact portion CA which exposes a portion of the auxiliary power electrode to electrically connect the auxiliary power electrode with the common electrode.

The auxiliary power line EVSS may be disposed to extend in a first direction (or a Y direction) of the display panel 110. For example, the auxiliary power line EVSS may be arranged in parallel with a data line DL. The auxiliary power line EVSS may be disposed between adjacent subpixels SP. For example, the auxiliary power line EVSS may be provided between two adjacent unit pixels of a plurality of unit pixels each including a plurality of subpixels SP1 to SP4 arranged in a direction (or a second direction or an X direction perpendicular to the first direction) parallel to a gate line GL, or may be provided between two adjacent subpixel groups of an arbitrary plurality of subpixel groups parallel to one another in the second direction (the X direction). In another embodiment of the present disclosure, the auxiliary power line EVSS may be disposed as a mesh type which extends in the first direction (or the Y direction) and the second direction (the X direction) of the display panel 110, but embodiments of the present disclosure are not limited thereto.

The contact portion CA may be disposed between adjacent subpixels SP. For example, the contact portion CA may be provided between adjacent subpixels SP with the auxiliary power line EVSS. The contact portion CA may be disposed to overlap the auxiliary power line EVSS. For example, the contact portion CA may be disposed to overlap the auxiliary power line EVSS, between adjacent subpixels SP. The contact portion CA may be provided for each horizontal line where subpixels SP are arranged in a direction (or a second direction or an X direction) parallel to a gate line GL, or may be provided for each of an arbitrary plurality of horizontal lines.

The auxiliary power line EVSS according to an embodiment of the present disclosure may be disposed to extend in the first direction (the Y direction) of the display panel 110, and at least a portion of the auxiliary power line EVSS may include a first portion EVSS_d1 and a second portion EVSS_d2, which are divisionally arranged apart from each other in the second direction (the X direction). For example, the auxiliary power line EVSS may be divided into the first portion EVSS_d1 and the second portion EVSS_d2 apart from each other in the second direction (the X direction) in a certain section and may extend in the first direction (the Y direction) and then may be connected as one body with each other. The contact portion CA may be disposed in a separation space between the first portion EVSS_d1 and the second portion EVSS_d2 of the auxiliary power line EVSS. For example, the contact portion CA may be disposed between the first portion EVSS_d1 and the second portion EVSS_d2 of the auxiliary power line EVSS.

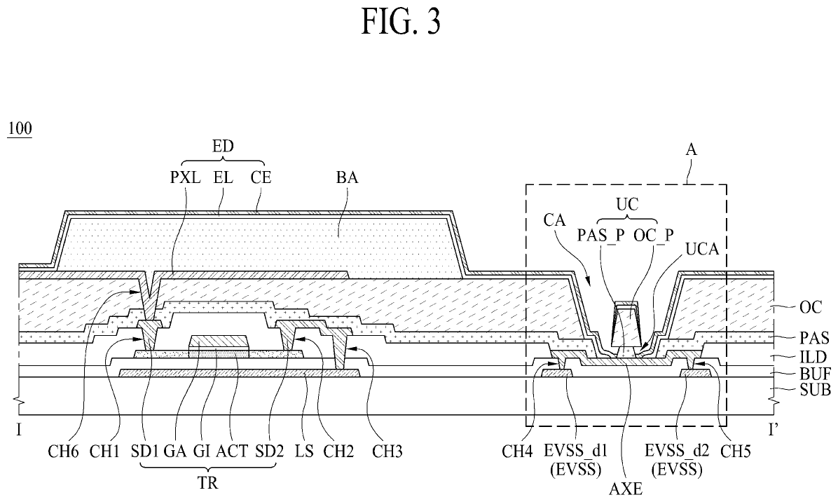

FIG. 3 is a diagram taken along line I-I′ of FIG. 2 in a light emitting display device 100 according to an embodiment of the present disclosure.

Referring to FIG. 3, the light emitting display device 100 according to an embodiment of the present disclosure may include a substrate SUB, a light blocking layer LS, a buffer layer BUF (or a first insulation layer), a thin film transistor (TFT) TR, a gate insulation layer GI (or a second insulation layer), an interlayer insulation layer ILD (or a third insulation layer), an auxiliary power electrode AXE, a passivation layer PAS (or a first protection layer), an overcoat layer OC (or a second protection layer), a light emitting device ED, a bank layer BA, and a contact portion CA.

The substrate SUB may be a base substrate and may include a glass or plastic material. For example, the substrate SUB may include a plastic material such as polyimide (PI), polyethylene terephthalate (PET), polyethylene naphthalate (PEN), or polycarbonate (PC) and may have a flexible characteristic, but embodiments of the present disclosure are not limited thereto.

A circuit element including various lines, the TFT TR, and a storage capacitor may be provided on the substrate SUB for each of a plurality of subpixels SP1 to SP4. For example, the lines may include a gate line GL, a data line DL, a first power line EVDD (a driving power line or a pixel power line), a second power line EVSS (an auxiliary power line or a common power line), and a reference line. Also, the TFT TR may include a driving TFT, a switching TFT, and a sensing TFT, but embodiments of the present disclosure are not limited thereto.

A light blocking layer LS and an auxiliary power line EVSS (a second power line or a common power line) may be disposed on the substrate SUB.

The light blocking layer LS may be disposed to overlap the TFT TR. The light blocking layer LS may overlap an active layer ACT of the TFT TR. For example, the light blocking layer LS may be disposed to overlap a channel region of the active layer ACT, on a plane. According to an embodiment of the present disclosure, the auxiliary power line EVSS may be disposed on the substrate SUB. For example, the auxiliary power line EVSS may apply an auxiliary power (or a low level voltage) to the common electrode CE to decrease a resistance of the common electrode CE.

The light blocking layer LS and the auxiliary power line EVSS may be formed of the same material on the same layer, on the substrate SUB. In this case, the light blocking layer LS and the auxiliary power line EVSS may be formed simultaneously through the same process, but embodiments of the present disclosure are not limited thereto.

The light blocking layer LS and the auxiliary power line EVSS may each be configured with one or more layers. For example, the light blocking layer LS and the auxiliary power line EVSS may each include an upper metal layer and a lower metal layer, and the lower metal layer may prevent or at least reduce the corrosion of a lower surface of the upper metal layer. For example, the lower metal layer may include a material which is lower in oxidation rate and better in anticorrosion than the upper metal layer, and for example, may include molybdenum (Mo), titanium (Ti), or a Mo—Ti alloy (MoTi), but embodiments of the present disclosure are not limited thereto. Also, the upper metal layer may include copper (Cu) which is lower in resistivity than that of the lower metal layer. Also, the upper metal layer may be configured to have a thickness which is greater than that of the lower metal layer, so as to decrease a total resistance, but embodiments of the present disclosure are not limited thereto.

According to an embodiment of the present disclosure, the auxiliary power line EVSS may be disposed to extend in a first direction (a Y direction) of the display panel 110, and at least a portion of the auxiliary power line EVSS may include a first portion EVSS_d1 and a second portion EVSS_d2, which are divisionally arranged apart from each other in a second direction (an X direction). For example, the auxiliary power line EVSS may be divided into the first portion EVSS_d1 and the second portion EVSS_d2 apart from each other in the second direction (the X direction) in a certain section and may extend in the first direction (the Y direction) and then may be connected as one body with each other. The contact portion CA may be disposed in a separation space between the first portion EVSS_d1 and the second portion EVSS_d2 of the auxiliary power line EVSS. For example, the contact portion CA may be disposed between the first portion EVSS_d1 and the second portion EVSS_d2 of the auxiliary power line EVSS.

The buffer layer BUF (or the first insulation layer) may be disposed on the substrate SUB to cover the light blocking layer LS and the auxiliary power line EVSS. The buffer layer BUF may be formed by stacking a single layer or a plurality of inorganic layers. For example, the buffer layer BUF may be formed of a single layer including silicon oxide (SiOx), silicon nitride (SiNx), and silicon oxynitride (SiOxNy). Alternatively, the buffer layer BUF may be formed of a multilayer where at least two of SiOx, SiNx, and SiOxNy are stacked. The buffer layer BUF may be formed all over an upper surface of the substrate SUB so as to block ions or impurities diffused from the substrate SUB and prevent or at least reduce the penetration of water into the light emitting device ED.

The TFT TR, the storage capacitor, and the auxiliary power electrode AXE may be disposed on the buffer layer BUF. The TFT TR and the storage capacitor may be disposed in each of the plurality of subpixels SP1 to SP4, on the buffer layer BUF. Also, the auxiliary power electrode AXE may be disposed between adjacent subpixels SP on the buffer layer BUF. The auxiliary power electrode AXE may be disposed to overlap the auxiliary power line EVSS, between adjacent subpixels SP. For example, the auxiliary power electrode AXE may be provided between two adjacent unit pixels of a plurality of unit pixels each including a plurality of subpixels SP1 to SP4, or may be provided for each of an arbitrary plurality of subpixel groups. Also, the auxiliary power electrode AXE may be provided for each horizontal line where subpixels SP are arranged in a direction (or the second direction or the X direction) parallel to a gate line GL at a position overlapping the auxiliary power line EVSS, or may be disposed for each of an arbitrary plurality of horizontal lines. However, embodiments of the present disclosure are not limited thereto.

The TFT TR may include the active layer ACT, a gate electrode GA overlapping the active layer ACT with the gate insulation layer GI (or the second insulation layer) therebetween, a first source/drain electrode SD1, and a second source/drain electrode SD2. Also, the storage capacitor may be formed in a triple structure where a first capacitor electrode which is patterned with the same material on the same layer as the light blocking layer LS, a second capacitor electrode which is patterned with the same material on the same layer as the gate electrode GA, and a third capacitor electrode, which is patterned with the same material on the same layer as the first and second source/drain electrodes SD1 and SD2 of the TFT TR, but embodiments of the present disclosure are not limited thereto. According to another embodiment of the present disclosure, various lines may be disposed on the buffer layer BUF. For example, the various lines may include a gate line GL, a data line DL, a first power line EVDD (a driving power line or a pixel power line), and a reference line, which include the same material as that of the gate electrode GA or the first and second source/drain electrodes SD1 and SD2, but embodiments of the present disclosure are not limited thereto.

The active layer ACT of the TFT TR may include a silicon-based or oxide-based semiconductor material and may be formed on the buffer layer BUF. The active layer ACT may include a channel region overlapping the gate electrode GA and a source/drain region connected with the first and second source/drain electrodes SD1 and SD2.

The gate insulation layer GI (or the second insulation layer) may be formed on the active layer ACT. The gate insulation layer GI may be disposed on the channel region of the active layer ACT and may insulate the active layer ACT from the gate electrode GA. The gate insulation layer GI may include an inorganic insulating material. For example, the gate insulation layer GI may include SiOx, SiNx, SiOxNy, or a multilayer thereof, but embodiments of the present disclosure are not limited thereto.

The gate electrode GA may be formed on the gate insulation layer GI (or the second insulation layer). The gate electrode GA may be disposed to face the active layer ACT with the gate insulation layer GI therebetween. Also, the gate electrode GA may include a single layer or a multilayer including one material, selected from among the group comprising copper (Cu), molybdenum (Mo), aluminum (Al), chromium (Cr), gold (Au), titanium (Ti), nickel (Ni), neodymium (Nd), tantalum (Ta), and tungsten (W), or an alloy thereof. Also, the second capacitor electrode configuring a portion of the storage capacitor may be formed of the same material as that of the gate electrode GA, on the buffer layer BUF. In this case, the gate electrode GA of the TFT TR and the second capacitor electrode of the storage capacitor may be formed simultaneously through the same process, but embodiments of the present disclosure are not limited thereto. The gate insulation layer GI may be patterned along with the gate electrode GA and the second capacitor electrode and may be disposed under each of the gate electrode GA and the second capacitor electrode.

The interlayer insulation layer ILD (or the third insulation layer) covering the gate electrode GA may be formed on the buffer layer BUF. Also, the interlayer insulation layer ILD may be formed to cover the second capacitor electrode of the storage capacitor. The interlayer insulation layer ILD may protect the TFT TR. The interlayer insulation layer ILD may include an inorganic insulating material. For example, the interlayer insulation layer ILD may include SiOx, SiNx, SiOxNy, or a multilayer thereof, but embodiments of the present disclosure are not limited thereto.

The first and second source/drain electrodes SD1 and SD2 may be formed on the interlayer insulation layer ILD (or the third insulation layer). A corresponding region of the interlayer insulation layer ILD may be removed for attaching the active layer ACT on the first and second source/drain electrodes SD1 and SD2. For example, the first and second source/drain electrodes SD1 and SD2 may contact the active layer ACT and may be electrically connected with the active layer ACT through a contact hole passing through the interlayer insulation layer ILD. Also, the second source/drain electrode SD2 may be electrically connected with the active layer ACT through a second contact hole CH2 passing through the interlayer insulation layer ILD. Also, one of the first source/drain electrode SD1 and the second source/drain electrode SD2 may be connected with the light blocking layer LS through a third contact hole CH3 passing through the interlayer insulation layer ILD and the buffer layer BUF. For example, the light blocking layer LS may include a conductive material, and when the light blocking layer LS is floated, the active layer ACT may be adversely affected thereby. Accordingly, one of the first source/drain electrode SD1 and the second source/drain electrode SD2 may be electrically connected with the light blocking layer LS to allow the light blocking layer LS not to be floated, thereby preventing or at least reducing the adverse effect on the active layer ACT.

The first and second source/drain electrodes SD1 and SD2 may each be formed of a single layer or a multilayer. When each of the first and second source/drain electrodes SD1 and SD2 is formed of a single layer, each of the first and second source/drain electrodes SD1 and SD2 may include one material, selected from among the group comprising Cu, Mo, Al, Cr, Au, Ti, Ni, Nd, Ta, and W, or an alloy thereof. Alternatively, when each of the first and second source/drain electrodes SD1 and SD2 is formed of a multilayer, each of the first and second source/drain electrodes SD1 and SD2 may be formed of a double layer of Mo/Al—Nd, Mo/Al, Ti/Al, or Cu/MoTi. Alternatively, each of the first and second source/drain electrodes SD1 and SD2 may be formed of a triple layer of Mo/Al-Nd/Mo, Mo/Al/Mo, Ti/Al/Ti, or MoTi/Cu/MoTi, but embodiments of the present disclosure are not limited thereto. According to another embodiment of the present disclosure, the first and second source/drain electrodes SD1 and SD2 may include the same material as that of the gate electrode GA, but embodiments of the present disclosure are not limited thereto.

According to an embodiment of the present disclosure, the interlayer insulation layer ILD may include an opening portion ILD_H which is formed by removing at least a portion of the interlayer insulation layer ILD. The auxiliary power electrode AXE may be disposed in the opening portion ILD_H of the interlayer insulation layer ILD. The auxiliary power electrode AXE may be disposed on the buffer layer BUF exposed through the opening portion ILD_H of the interlayer insulation layer ILD. The auxiliary power electrode AXE may have a shape corresponding to the opening portion ILD_H of the interlayer insulation layer ILD. For example, an edge end of the auxiliary power electrode AXE may have a shape corresponding to a lateral surface of the opening portion ILD_H of the interlayer insulation layer ILD. At least a portion of the edge end of the auxiliary power electrode AXE may have a reverse tapered shape. For example, the lateral surface of the opening portion ILD_H of the interlayer insulation layer ILD may include a sloped surface, and the auxiliary power electrode AXE may have a reverse tapered shape corresponding to a sloped surface of the opening portion ILD_H. According to an embodiment of the present disclosure, the auxiliary power electrode AXE may include the same material as that of each of the first and second source/drain electrodes SD1 and SD2. For example, the auxiliary power electrode AXE may be formed simultaneously through the same process as the first and second source/drain electrodes SD1 and SD2.

The auxiliary power electrode AXE may apply an auxiliary power (a low level voltage or a common voltage), supplied through the auxiliary power line EVSS, to a common electrode CE (a cathode electrode or a second electrode). Also, the auxiliary power electrode AXE may reduce a resistance of the common electrode CE along with the auxiliary power line EVSS. Also, the auxiliary power electrode AXE may function as the third capacitor electrode of the storage capacitor. The auxiliary power electrode AXE may contact and be electrically connected with the auxiliary power line EVSS through contact holes CH4 and CH5 passing through the buffer layer BUF.

According to an embodiment of the present disclosure, at least a portion of the auxiliary power line EVSS may include a first portion EVSS_d1 and a second portion EVSS_d2, which are divisionally arranged apart from each other, in a section corresponding to the contact portion CA. The auxiliary power electrode AXE may be disposed between the first portion EVSS_d1 and the second portion EVSS_d2 of the auxiliary power line EVSS, one end of the auxiliary power electrode AXE may overlap the first portion EVSS_d1 of the auxiliary power line EVSS, and the other end of the auxiliary power electrode AXE may overlap the second portion EVSS_d2 of the auxiliary power line EVSS. For example, the one end of the auxiliary power electrode AXE may contact and be electrically connected with the first portion EVSS_d1 of the auxiliary power line EVSS through a fourth contact hole CH4 passing through the buffer layer BUF. Also, the other end of the auxiliary power electrode AXE may contact and be electrically connected with the second portion EVSS_d2 of the auxiliary power line EVSS through a fifth contact hole CH5 passing through the buffer layer BUF.

The TFT TR, the storage capacitor, and the auxiliary power electrode AXE disposed on the substrate SUB may configure a circuit layer (or a TFT array layer).

The passivation layer PAS (or the first protection layer) may be disposed on the circuit layer including the TFT TR, the storage capacitor, and the auxiliary power electrode AXE. The passivation layer PAS may be provided to cover the TFT TR, the storage capacitor, and the auxiliary power electrode AXE. The passivation layer PAS may protect the TFT TR, the storage capacitor, and the auxiliary power electrode AXE of the circuit layer and may include an inorganic insulating material. For example, the passivation layer PAS may include SiOx, SiNx, SiOxNy, or a multilayer thereof, but embodiments of the present disclosure are not limited thereto.

The overcoat layer OC (a second protection layer or a planarization layer) may be disposed on the passivation layer PAS. The overcoat layer OC may planarize a lower step height and may include an organic insulating material. For example, the overcoat layer OC may include at least one of organic materials such as photo acryl, polyimide, benzocyclobutene resin, and acrylate, but embodiments of the present disclosure are not limited thereto.

A pixel electrode PXL (an anode electrode or a first electrode) may be disposed on the overcoat layer OC (the second protection layer or the planarization layer). The pixel electrode PXL may be disposed in each of the plurality of subpixels SP1 to SP4 on the overcoat layer OC. The pixel electrode PXL may be connected with the first source/drain electrode SD1 of the TFT TR through a sixth contact hole CH6 passing through the overcoat layer OC and the passivation layer PAS. Alternatively, the pixel electrode PXL may be connected with the second source/drain electrode SD2 of the TFT TR. An emission layer EL (or an organic emission layer) and the common electrode CE (a cathode electrode or a second electrode) may be disposed on the pixel electrode PXL. The pixel electrode PXL, the emission layer EL, and the common electrode CE may configure a light emitting device ED.

The pixel electrode PXL (the anode electrode or the first electrode) may include metal, an alloy thereof, or a combination of metal and oxide metal. For example, the pixel electrode PXL may be formed in a multi-layer structure including a transparent conductive layer and an opaque conductive layer which is high in reflection efficiency. The transparent conductive layer of the pixel electrode PXL may include a material, having a relatively large work function value, such as indium tin oxide (ITO) or indium zinc oxide (IZO), and the opaque conductive layer may be formed of a single layer or a multilayer including one material, selected from among the group comprising silver (Ag), Al, Cu, Mo, Ti, Ni, Cr, and W, or an alloy thereof. For example, the pixel electrode PXL may be formed in a structure where a transparent conductive layer, an opaque conductive layer, and a transparent conductive layer are sequentially stacked or may be formed in a structure where a transparent conductive layer and an opaque conductive layer are sequentially stacked, but embodiments of the present disclosure are not limited thereto.

The bank layer BA may be disposed on the pixel electrode PXL and the overcoat layer OC. The bank layer BA may cover an edge portion of the pixel electrode PXL and may define an opening portion of the subpixel SP. The bank layer BA may include an organic material such as polyimide, acrylate, or benzocyclobutene series resin, but embodiments of the present disclosure are not limited thereto. A center portion of the pixel electrode PXL exposed by the bank layer BA may be defined as an emission region. Also, a portion covered by the bank layer BA may be defined as a non-emission region.

The contact portion CA may pass through the passivation layer PAS and the overcoat layer OC to expose a portion of the auxiliary power electrode AXE. That is to say that the passivation layer PAS and the overcoat layer OC do not cover or only partially cover the auxiliary power electrode AXE in the region of the contact portion CA. An undercut structure UC including an undercut region UCA may be disposed on the auxiliary power electrode AXE exposed by the contact portion CA.

The undercut structure UC may be disposed on a portion of the auxiliary power electrode AXE and may include the undercut region UCA. The undercut structure UC may be provided in an island pattern on a portion of the auxiliary power electrode AXE, and the auxiliary power electrode AXE may be exposed at a peripheral perimeter of the undercut structure UC. The auxiliary power electrode AXE exposed at the peripheral perimeter of the undercut structure UC may contact and may be electrically connected with the common electrode CE (the cathode electrode or the second electrode), in the contact portion CA. The undercut structure UC may include the same material as that of each of the passivation layer PAS and the overcoat layer OC. The undercut structure UC may include a first pattern PAS_P including the same material as that of the passivation layer PAS and a second pattern OC_P including the same material as that of the overcoat layer OC.

The emission layer EL may be disposed on the pixel electrode PXL and the bank layer BA. Also, the emission layer EL may be disposed on the second pattern OC_P of the undercut structure UC. The emission layer EL may be disposed on the auxiliary power electrode AXE exposed through the contact portion CA. The emission layer EL may be disconnected in the undercut region UCA by the undercut structure UC disposed at the contact portion CA. For example, the emission layer EL may include a material which is not good in step coverage. Accordingly, the emission layer EL may have an area which is disposed on the auxiliary power electrode AXE and is minimized or reduced by the undercut structure UC and may be disconnected in the undercut region UCA of the undercut structure UC.

The common electrode CE (the cathode electrode or the second electrode) may be disposed on the emission layer EL. The common electrode CE may be disposed on the emission layer EL of the second pattern OC_P of the undercut structure UC. The common electrode CE may be disposed on the pixel electrode PXL and the emission layer EL to configure the light emitting device ED. The common electrode CE may be widely provided on an entire surface of the substrate SUB. The common electrode CE may include a transparent conductive material such as ITO or IZO, or may include Ag, Al, magnesium (Mg), calcium (Ca), or an alloy thereof having a thin thickness enabling transmission of light, but embodiments of the present disclosure are not limited thereto.

The common electrode CE may be disposed on and electrically connected with the auxiliary power electrode AXE exposed by the contact portion CA. The common electrode CE may be disposed to cover the bank layer BA and may be disposed on the auxiliary power electrode AXE in the undercut region UCA of the undercut structure UC. For example, the common electrode CE may include a material which is good in step coverage. The common electrode CE may be better in step coverage than the emission layer EL formed by an evaporation process, and thus, the emission layer EL may be disconnected in the undercut region UCA of the undercut structure UC and may be formed on the auxiliary power electrode AXE exposed at the outside. Therefore, the emission layer EL may not be disposed on the auxiliary power electrode AXE in the undercut region UCA of the undercut structure UC, but the common electrode CE may be disposed on the auxiliary power electrode AXE where the emission layer EL is not disposed and may be electrically connected with the auxiliary power electrode AXE.

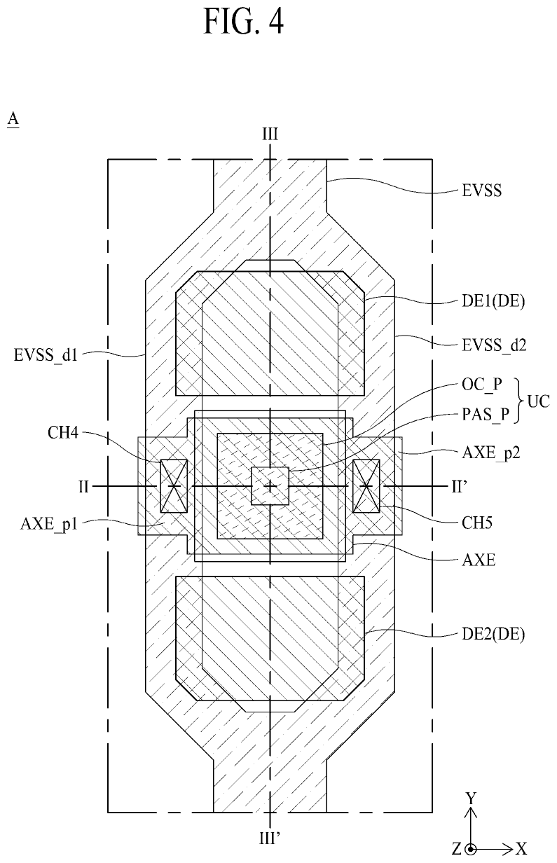

The light emitting display device 100 according to an embodiment of the present disclosure may further include at least one dummy electrode disposed at a periphery of the auxiliary power electrode AXE in the contact portion CA. The auxiliary power electrode AXE and the at least one dummy electrode may be electrically disconnected from or connected with each other. According to an embodiment of the present disclosure, when a contact defect occurs between the auxiliary power electrode AXE and the common electrode CE, the at least one dummy electrode may recover an electrical connection between the auxiliary power electrode AXE and the common electrode CE through laser welding, and thus, a contact defect of the auxiliary power electrode AXE may be repaired. Hereinafter, a detailed configuration of the contact portion CA according to an embodiment of the present disclosure will be described with reference to FIGS. 4 to 13.

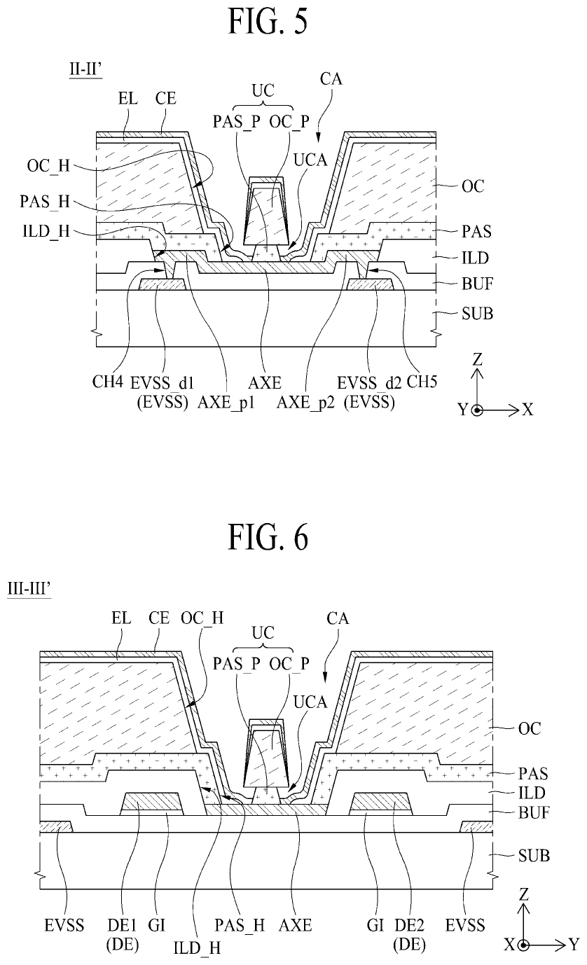

FIG. 4 is a plan view illustrating a contact portion illustrated in a region A of FIG. 3 according to an embodiment of the present disclosure. FIG. 5 is a cross-sectional view taken along line II-II′ of FIG. 4. FIG. 6 is a cross-sectional view taken along line III-III′ of FIG. 4.

Referring to FIGS. 4 to 6, the light emitting display device 100 according to an embodiment of the present disclosure may include a contact portion CA which exposes a portion of an auxiliary power electrode AXE. The contact portion CA may pass through a passivation layer PAS (or a first protection layer) and an overcoat layer OC (or a second protection layer) to expose a portion of the auxiliary power electrode AXE. An undercut structure UC including an undercut region UCA may be provided on the auxiliary power electrode AXE exposed by the contact portion CA.

An auxiliary power line EVSS may be disposed on a substrate SUB. The auxiliary power line EVSS may extend in a first direction (a Y direction), and at least a portion of the auxiliary power line EVSS may include a first portion EVSS_d1 and a second portion EVSS_d2, which are divisionally arranged apart from each other in a second direction (an X direction). For example, a portion of the auxiliary power line EVSS may be divided into the first portion EVSS_d1 and the second portion EVSS_d2 apart from each other in the second direction (the X direction) in a section corresponding to the contact portion CA and may extend in the first direction (the Y direction) and then may be connected as one body with each other. The auxiliary power line EVSS and at least one dummy electrode DE may be disposed in a separation space between the first portion EVSS_d1 and the second portion EVSS_d2 of the auxiliary power line EVSS. The auxiliary power line EVSS and the at least one dummy electrode DE may be apart from each other on a plane.

The auxiliary power electrode AXE may be disposed at a center in the first direction (the Y direction) in the separation space between the first portion EVSS_d1 and the second portion EVSS_d2 of the auxiliary power line EVSS. The at least one dummy electrode DE may be disposed at at least one of one side and the other side of the auxiliary power electrode AXE in the separation space between the first portion EVSS_d1 and the second portion EVSS_d2 of the auxiliary power line EVSS. That is to say that the at least one dummy electrode DE may be disposed at one side or two sides of the auxiliary power electrode AXE. For example, the at least one dummy electrode DE may include a first dummy electrode DE1 and a second dummy electrode DE2 which are respectively disposed at one side and the other side of the auxiliary power electrode AXE with the auxiliary power electrode AXE therebetween.

The at least one dummy electrode DE may be disposed on the buffer layer BUF. An interlayer insulation layer ILD (or a third insulation layer) may be disposed on the at least one dummy electrode DE. The interlayer insulation layer ILD may be disposed on the buffer layer BUF to cover the at least one dummy electrode DE. The at least one dummy electrode DE may be disposed apart from the auxiliary power electrode AXE in the first direction (the Y direction). The interlayer insulation layer ILD may be disposed between the at least one dummy electrode DE and the auxiliary power electrode AXE. The at least one dummy electrode DE may include a first dummy electrode DE1 and a second dummy electrode DE2 which are arranged with the auxiliary power electrode AXE in the first direction (the Y direction). For example, the first dummy electrode DE1 may be disposed apart from one side of the auxiliary power electrode AXE in the first direction (the Y direction). Also, the second dummy electrode DE2 may be disposed apart from the other side of the auxiliary power electrode AXE in the first direction (the Y direction).

A gate insulation layer GI (or a second insulation layer) may be disposed between the at least one dummy electrode DE and the buffer layer BUF. The at least one dummy electrode DE may be formed of the same material on the same layer as a gate electrode GA of a TFT TR. For example, the at least one dummy electrode DE may be formed simultaneously through the same process as the gate electrode GA on the gate insulation layer GI. The gate insulation layer GI may be patterned along with the at least one dummy electrode DE and the gate electrode GA and may be disposed under each of the at least one dummy electrode DE and the gate electrode GA. The at least one dummy electrode DE may be disposed between the buffer layer BUF and the interlayer insulation layer ILD and may be in an electrically disconnected floating state. For example, the at least one dummy electrode DE may not be connected with and may be electrically disconnected from an auxiliary power line EVSS under the buffer layer BUF. Also, the at least one dummy electrode DE may not be connected with and may be electrically disconnected from the auxiliary power electrode AXE with the interlayer insulation layer ILD therebetween.

The auxiliary power electrode AXE may be disposed on the buffer layer BUF (or the first insulation layer). The auxiliary power electrode AXE may be disposed in an opening portion ILD_H which is formed by removing at least a portion of the interlayer insulation layer ILD (or the third insulation layer). The auxiliary power electrode AXE may be disposed on the buffer layer BUF exposed through the opening portion ILD_H of the interlayer insulation layer ILD. The auxiliary power electrode AXE may be disposed between the first dummy electrode DE1 and the second dummy electrode DE2 of the at least one dummy electrode DE in the first direction (the Y direction). The interlayer insulation layer ILD may be disposed between the auxiliary power electrode AXE and the at least one dummy electrode DE. For example, one side of the auxiliary power electrode AXE may be apart from the first dummy electrode DE1 in the first direction (the Y direction). Also, the other side of the auxiliary power electrode AXE may be apart from the second dummy electrode DE2 in the first direction (the Y direction).

The auxiliary power electrode AXE may have a thickness which differs from that of the at least one dummy electrode DE. The auxiliary power electrode AXE may have a thickness which is less than or equal to that of the at least one dummy electrode DE. For example, the auxiliary power electrode AXE may be formed through a process which differs from the at least one dummy electrode DE and may be formed to have a thickness which is less than that of the at least one dummy electrode DE. The auxiliary power electrode AXE may have a height which differs from that of the at least one dummy electrode DE, with respect to an upper surface of the substrate SUB. The auxiliary power electrode AXE may have a height which is lower than or equal to that of the at least one dummy electrode DE, with respect to the upper surface of the substrate SUB. For example, the auxiliary power electrode AXE may have a height which is lower than that of the at least one dummy electrode DE, with respect to the buffer layer BUF on the substrate SUB. The auxiliary power electrode AXE may be disposed on an upper surface of the buffer layer BUF and may have a height which is lower than that of the at least one dummy electrode DE disposed on the gate insulation layer GI on the buffer layer BUF.

The auxiliary power electrode AXE may be formed of the same material as that of source/drain electrodes SD1 and SD2 of the TFT TR on a layer which differs from the source/drain electrodes SD1 and SD2 of the TFT TR. For example, an opening portion ILD_H exposing at least a portion of the buffer layer BUF may be formed in the interlayer insulation layer ILD, and the auxiliary power electrode AXE may be formed simultaneously through the same process as the source/drain electrodes SD1 and SD2, on the buffer layer BUF exposed through the opening portion ILD_H of the interlayer insulation layer ILD. The auxiliary power electrode AXE may have a shape corresponding to the opening portion ILD_H of the interlayer insulation layer ILD. For example, an edge end of the auxiliary power electrode AXE may have a shape corresponding to a lateral surface of the opening portion ILD_H of the interlayer insulation layer ILD. At least a portion of the edge end of the auxiliary power electrode AXE may have a reverse tapered shape. For example, the lateral surface of the opening portion ILD_H of the interlayer insulation layer ILD may include a sloped surface, and the auxiliary power electrode AXE may have a reverse tapered shape corresponding to a sloped surface of the opening portion ILD_H.

The auxiliary power electrode AXE may be disposed in the separation space between the first portion EVSS_d1 and the second portion EVSS_d2 of the auxiliary power line EVSS. At least a portion of the auxiliary power electrode AXE may overlap the first portion EVSS_d1 and the second portion EVSS_d2 of the auxiliary power line EVSS. The auxiliary power electrode AXE may include a first protrusion portion AXE_p1 and a second protrusion portion AXE_p2, which protrude in the second direction (the X direction) in the separation space between the first portion EVSS_d1 and the second portion EVSS_d2 of the auxiliary power line EVSS and respectively overlap the first portion EVSS_d1 and the second portion EVSS_d2 of the auxiliary power line EVSS.

The auxiliary power electrode AXE may be disposed between the first portion EVSS_d1 and the second portion EVSS_d2 of the auxiliary power line EVSS, the first protrusion portion AXE_p1 of the auxiliary power electrode AXE may overlap the first portion EVSS_d1 of the auxiliary power line EVSS, and the second protrusion portion AXE_p2 of the auxiliary power electrode AXE may overlap the second portion EVSS_d2 of the auxiliary power line EVSS. For example, the first protrusion portion AXE_p1 of the auxiliary power electrode AXE may contact and be electrically connected with the first portion EVSS_d1 of the auxiliary power line EVSS through a fourth contact hole CH4 passing through the buffer layer BUF. Also, the second protrusion portion AXE_p2 of the auxiliary power electrode AXE may contact and be electrically connected with the second portion EVSS_d2 of the auxiliary power line EVSS through a fifth contact hole CH5 passing through the buffer layer BUF.

The passivation layer PAS (or the first protection layer) may be disposed on the interlayer insulation layer ILD. The passivation layer PAS may be formed to cover an edge of the auxiliary power electrode AXE. The passivation layer PAS may include a first opening portion PAS_H which exposes a portion of the auxiliary power electrode AXE. An undercut structure UC including an undercut region UCA may be disposed on an upper surface of the auxiliary power electrode AXE exposed by the first opening portion PAS_H of the passivation layer PAS. For example, the first opening portion PAS_H of the passivation layer PAS may be formed in a shape surrounding a periphery of the undercut structure UC with the undercut structure UC therebetween. Also, the first opening portion PAS_H of the passivation layer PAS may have a size which is less than that of the opening portion ILD_H of the interlayer insulation layer ILD. For example, the passivation layer PAS may cover the opening portion ILD_H of the interlayer insulation layer ILD and may expose a portion of the auxiliary power electrode AXE through the first opening portion PAS_H of the passivation layer PAS. The undercut structure UC may include a first pattern PAS_P and a second pattern OC_P, and the first pattern PAS_P of the undercut structure UC may include the same material as that of the passivation layer PAS.

The overcoat layer OC may include a second opening portion OC_H which is greater than or equal to the first opening portion PAS_H of the passivation layer PAS. For example, the second opening portion OC_H of the overcoat layer OC may be formed in a shape corresponding to a perimeter of the first opening portion PAS_H of the passivation layer PAS and may have a size which is greater than that of the first opening portion PAS_H. A portion of the passivation layer PAS may be exposed through the second opening portion OC_H of the overcoat layer OC. For example, the second opening portion OC_H of the overcoat layer OC may be formed in a shape surrounding the periphery of the undercut structure UC with the undercut structure UC therebetween. The undercut structure UC may include a first pattern PAS_P and a second pattern OC_P, and the second pattern OC_P of the undercut structure UC may include the same material as that of the overcoat layer OC.

The first opening portion PAS_H of the passivation layer PAS and the second opening portion OC_H of the overcoat layer OC may include a stepped region which is formed along an upper surface of the overcoat layer OC, a lateral surface of the second opening portion OC_H, an upper surface of the passivation layer PAS, and a lateral surface of the first opening portion PAS_H.

The undercut structure UC may be disposed on a portion of the auxiliary power electrode AXE and may include an undercut region UCA. For example, the undercut structure UC may be disposed on a portion of the auxiliary power electrode AXE exposed through the first opening portion PAS_H of the passivation layer PAS and the second opening portion OC_H of the overcoat layer OC. The undercut structure UC may be formed to have an island pattern at a center portion of the auxiliary power electrode AXE exposed through the first opening portion PAS_H and the second opening portion OC_H. The undercut region UCA of the undercut structure may configure an exposure region of the auxiliary power electrode AXE where an emission layer EL is not disposed. The common electrode CE may be disposed in the exposure region of the auxiliary power electrode AXE and may be electrically connected with the auxiliary power electrode AXE.

The undercut structure UC may include a first pattern PAS_P and a second pattern OC_P. The first pattern PAS_P and the second pattern OC_P of the undercut structure UC may include an inorganic insulating material or an organic insulating material. For example, the first pattern PAS_P of the undercut structure UC may include the same material as that of the passivation layer PAS. The second pattern OC_P of the undercut structure UC may include the same material as that of the overcoat layer OC.

The first pattern PAS_P may be formed on an upper surface of the auxiliary power electrode AXE. The first pattern PAS_P may be formed with an island pattern and may include an upper surface which has a first width and contacts the second pattern OC_P, a lower surface which has a second width greater than the first width and contacts the auxiliary power electrode AXE, and a slope surface between the upper surface and the lower surface. For example, a sloped surface of the first pattern PAS_P may be arranged at the same slope angle as that of a sloped surface of the first opening portion PAS_H of the passivation layer PAS. For example, the first pattern PAS_P may be formed of the same material on the same layer as the passivation layer PAS. The first pattern PAS_P may be formed together through the same process as the first opening portion PAS_H of the passivation layer PAS.

The second pattern OC_P may be formed on an upper surface of the first pattern PAS_P. The second pattern OC_P may be supported by the first pattern PAS_P. The second pattern OC_P may be formed on the first pattern PAS_P to have an island pattern and may be formed in a shape which protrudes from the first pattern PAS_P. The undercut region UCA may be formed under an edge of the second pattern OC_P protruding from a lateral surface of the first pattern PAS_P. The second pattern OC_P may have a width which is greater than the first and second widths of the first pattern PAS_P and may include a lower surface which has a width which is greater than the first and second widths of the first pattern PAS_P and contacts the first pattern PAS_P, an upper surface which is less in width than the lower surface, and a slope surface between the upper surface and the lower surface. For example, a slope surface of the second pattern OC_P may be arranged at the same slope angle as that of a slope surface of the second opening portion OC_H of the overcoat layer OC. For example, the second pattern OC_P may be formed of the same material on the same layer as the overcoat layer OC. The second pattern OC_P may be formed together through the same process as the second opening portion OC_H of the overcoat layer OC.

The emission layer EL may be disposed on the pixel electrode PE and the bank layer BA. Also, the emission layer EL may be disposed on the second pattern OC_P of the undercut structure UC. The emission layer EL may be partially disposed on the auxiliary power electrode AXE exposed through the contact portion CA. The emission layer EL may be partially formed on the auxiliary power electrode AXE along a stepped region formed by the overcoat layer OC and the passivation layer PAS in the contact portion CA. The emission layer EL may be disconnected in the undercut region UCA by the undercut structure UC disposed at the contact portion CA. For example, the emission layer EL may include a material which is not good in step coverage. Accordingly, the emission layer EL may have an area which is disposed on the auxiliary power electrode AXE and is minimized or reduced by the undercut structure UC and may be disconnected in the undercut region UCA of the undercut structure UC.

The common electrode CE (the cathode electrode or the second electrode) may be disposed on the emission layer EL. The common electrode CE may be disposed on the emission layer EL on the second pattern OC_P of the undercut structure UC. The common electrode CE may overlap the pixel electrode PXL and the emission layer EL to configure a light emitting device ED. The common electrode CE may be widely provided on an entire surface of the substrate SUB. The common electrode CE may include a transparent conductive material such as ITO or IZO, or may include Ag, Al, Mg, Ca, or an alloy thereof having a thin thickness enabling transmission of light, but embodiments of the present disclosure are not limited thereto.

The common electrode CE may be formed on the emission layer EL along a stepped region formed by the overcoat layer OC and the passivation layer PAS in the contact portion CA. The common electrode CE may be formed on the auxiliary power electrode AXE corresponding to the undercut region UCA by the undercut structure UC disposed in the contact portion CA. For example, the common electrode CE may include a material which is good in step coverage. The common electrode CE may be better in step coverage than the emission layer EL formed by an evaporation process, and thus, the emission layer EL may be disconnected in the undercut region UCA of the undercut structure UC and may be formed on the auxiliary power electrode AXE exposed at the outside. Therefore, the emission layer EL may not be disposed on the auxiliary power electrode AXE in the undercut region UCA of the undercut structure UC, but the common electrode CE may be disposed on the auxiliary power electrode AXE where the emission layer EL is not disposed and may be electrically connected with the auxiliary power electrode AXE.

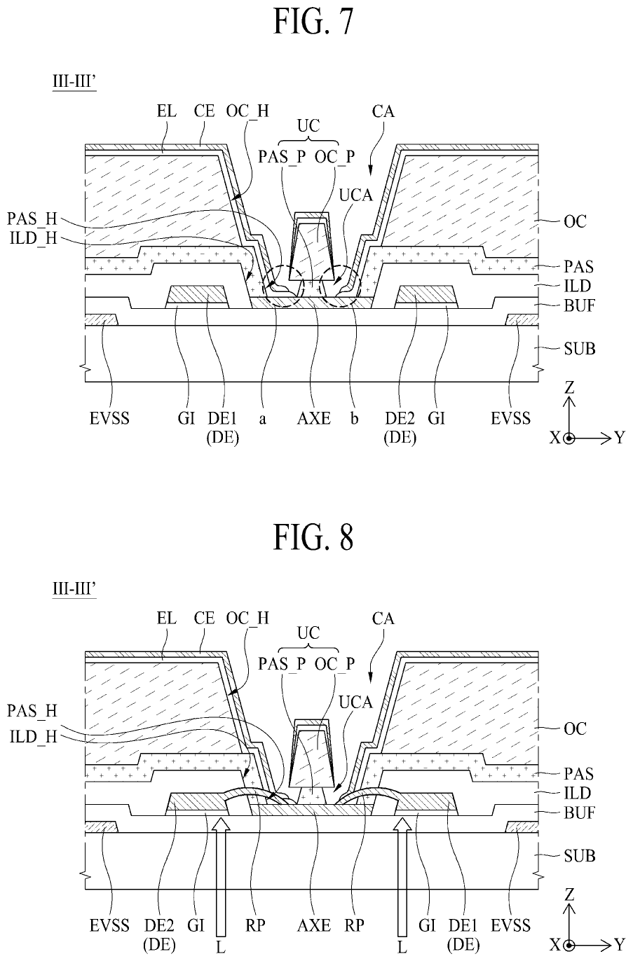

FIGS. 7 and 8 are diagrams for describing a contact defect occurring in a contact portion according to an embodiment of the present disclosure and a process of repairing the contact defect.

Referring to FIGS. 7 and 8, a light emitting display device 100 according to an embodiment of the present disclosure may have a repair structure which may repair contact defects a and b between an auxiliary power electrode AXE and a common electrode CE when the contact defects a and b occur between the auxiliary power electrode AXE and the common electrode CE in a contact portion CA.

For example, as in ‘a’ illustrated in FIG. 7, when an emission layer EL is not disconnected in an undercut region UCA and is formed to penetrate up to the undercut region UCA, an electrical connection between the auxiliary power electrode AXE and the common electrode CE may not be smoothly performed. Alternatively, as in ‘b’ illustrated in FIG. 7, when the undercut region UCA is not formed up to the undercut region UCA because deposition of the common electrode CE is insufficient, the electrical connection between the auxiliary power electrode AXE and the common electrode CE may not be smoothly performed.

When the contact defects a and b occur between the auxiliary power electrode AXE and the common electrode CE, at least one dummy electrode DE according to an embodiment of the present disclosure may function as the repair structure for recovering the electrical connection between the auxiliary power electrode AXE and the common electrode CE.

Referring to FIG. 8, the at least one dummy electrode DE according to an embodiment of the present disclosure may include a first dummy electrode DE1 and a second dummy electrode DE2 which are respectively disposed at one side and the other side of the auxiliary power electrode AXE. The first dummy electrode DE1 and the second dummy electrode DE2 of the at least one dummy electrode DE may be a welding region onto which a laser beam L is irradiated, in a repair process. For example, a portion where the first dummy electrode DE1 and the second dummy electrode DE2 overlap a separation space between a first portion EVSS_d1 and a second portion EVSS_d2 of an auxiliary power line EVSS may be the welding region onto which the laser beam L is irradiated.

In the repair process, the laser beam L may not be directly irradiated onto the auxiliary power electrode AXE and may be irradiated onto the at least one dummy electrode DE disposed at a periphery of the auxiliary power electrode AXE, and thus, laser welding may be performed on the at least one dummy electrode DE, thereby preventing or at least reducing the damage of an undercut structure UC on the auxiliary power electrode AXE and smoothly recovering the electrical connection between the auxiliary power electrode AXE and the common electrode CE through a modified repair pattern RP of the at least one dummy electrode DE.

According to an embodiment of the present disclosure, the auxiliary power electrode AXE may have a thickness which is less than that of at least one dummy electrode DE or may have a height which is lower than that of the at least one dummy electrode DE from an upper surface of a substrate SUB, or an edge end thereof adjacent to the at least one dummy electrode DE may have a reverse tapered shape. The repair pattern RP based on laser welding on the at least one dummy electrode DE may more smoothly contact the auxiliary power electrode AXE, and thus, welding may be more smoothly performed and the electrical connection between the auxiliary power electrode AXE and the common electrode CE may be more smoothly recovered.

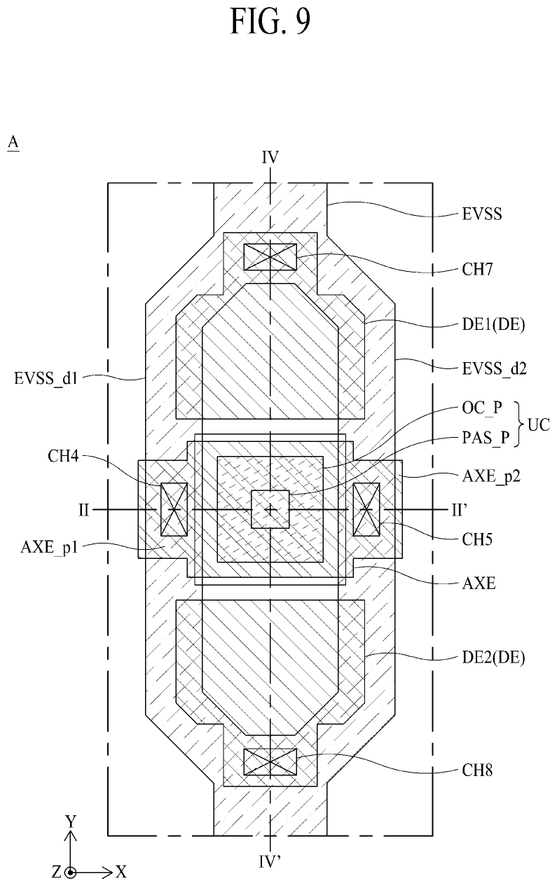

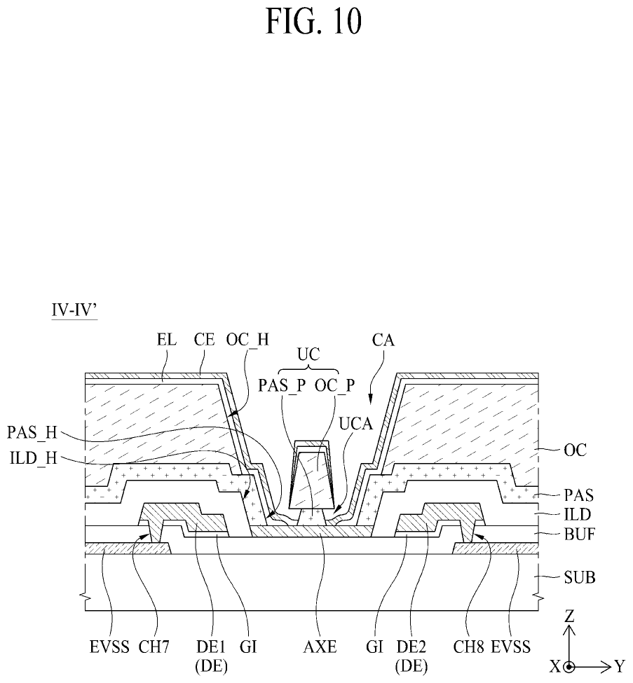

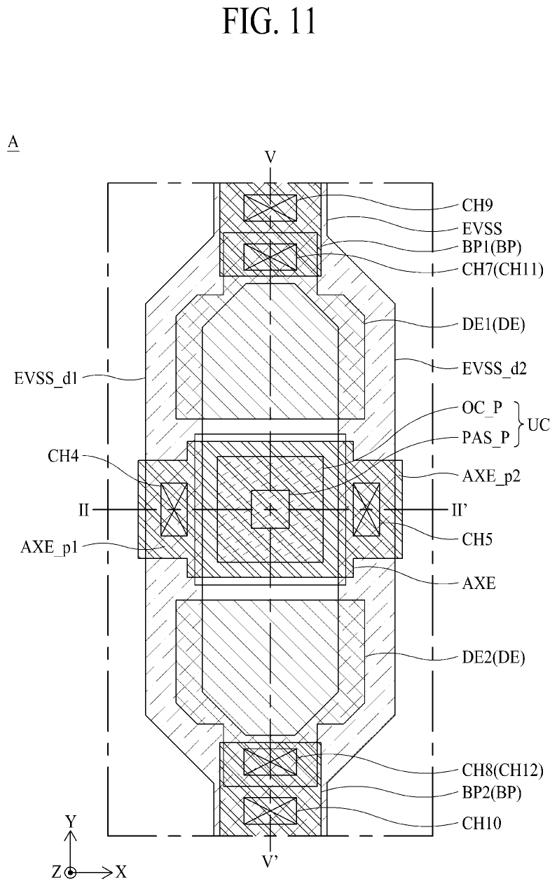

FIG. 9 is a plan view illustrating a contact portion illustrated in a region A of FIG. 3 according to another embodiment of the present disclosure. FIG. 10 is a cross-sectional view taken along line IV-IV′ of FIG. 9. FIGS. 9 and 10 illustrate an embodiment implemented by modifying a configuration of at least one dummy electrode in the light emitting display device 100 described above with reference to FIGS. 1 to 8. In the following description, therefore, the other elements except at least one dummy electrode and relevant elements are referred to by like reference numerals, and repeated descriptions thereof are omitted or will be briefly given. Also, a cross-sectional view taken along line II-II′ in FIG. 9 illustrates substantially the same elements as FIG. 5, and thus, the illustration thereof is omitted.

Referring to FIGS. 9 and 10 in conjunction with FIG. 5, in a light emitting display device 100 according to another embodiment of the present disclosure, at least one dummy electrode DE may be electrically connected with an auxiliary power line EVSS.

The at least one dummy electrode DE according to another embodiment of the present disclosure may contact and be electrically connected with the auxiliary power line EVSS through contact holes CH7 and CH8 passing through a buffer layer BUF and a gate insulation layer GI.

The at least one dummy electrode DE may be disposed in a separation space between a first portion EVSS_d1 and a second portion EVSS_d2 of the auxiliary power line EVSS. At least a portion of the at least one dummy electrode DE may overlap the auxiliary power line EVSS. For example, the at least one dummy electrode DE may overlap a portion where the auxiliary power line EVSS is not divided into the first portion EVSS_d1 and the second portion EVSS_d2 and is provided as one body. A first dummy electrode DE1 and a second dummy electrode DE2 of the at least one dummy electrode DE may extend in a direction opposite to a first direction (a Y direction) and may overlap one end and the other end of the auxiliary power line EVSS with a separation space therebetween.

The first dummy electrode DE1 may be disposed between the first portion EVSS_d1 and the second portion EVSS_d2 of the auxiliary power line EVSS, and a portion of the first dummy electrode DE1 may overlap one end of the auxiliary power line EVSS where the first portion EVSS_d1 and the second portion EVSS_d2 of the auxiliary power line EVSS are coupled to each other. The first dummy electrode DE1 may contact and be electrically connected with the one end of the auxiliary power line EVSS through a seventh contact hole CH7 passing through a buffer layer BUF.

The second dummy electrode DE2 may be disposed between the first portion EVSS_d1 and the second portion EVSS_d2 of the auxiliary power line EVSS, and a portion of the second dummy electrode DE2 may overlap the other end of the auxiliary power line EVSS where the first portion EVSS_d1 and the second portion EVSS_d2 of the auxiliary power line EVSS are coupled to each other. The second dummy electrode DE2 may contact and be electrically connected with the other end of the auxiliary power line EVSS through an eighth contact hole CH8 passing through the buffer layer BUF.

According to another embodiment of the present disclosure, at least one dummy electrode DE may be electrically connected with the auxiliary power line EVSS and may not be electrically floated. Also, the at least one dummy electrode DE may be supplied with an auxiliary power (or a low level voltage) through the auxiliary power line EVSS. A repair pattern RP based on laser welding on the at least one dummy electrode DE may electrically contact a common electrode CE and may directly supply the auxiliary power, and thus, a contact defect of the common electrode CE may be more effectively repaired.

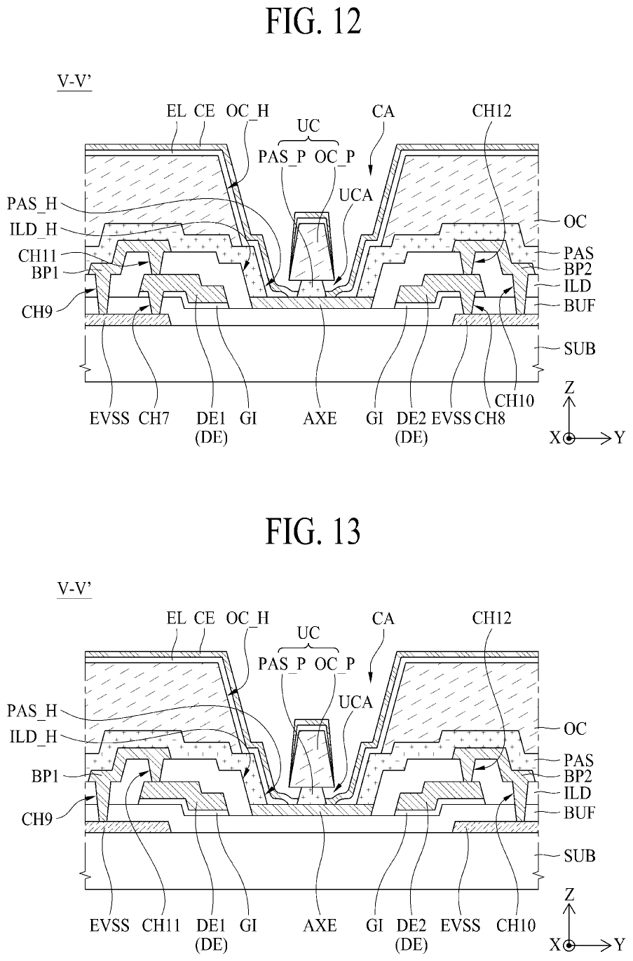

FIG. 11 is a plan view illustrating a contact portion illustrated in a region A of FIG. 3 according to another embodiment of the present disclosure. FIG. 12 is a cross-sectional view taken along line V-V′ of FIG. 11. FIG. 13 is another cross-sectional view taken along line V-V′ of FIG. 11. FIGS. 11 to 13 illustrate an embodiment where a configuration of a bridge pattern is added to the light emitting display device 100 described above with reference to FIGS. 1 to 10. In the following description, therefore, the other elements except a bridge pattern and relevant elements are referred to by like reference numerals, and repeated descriptions thereof are omitted or will be briefly given. Also, a cross-sectional view taken along line II-II′ in FIG. 11 illustrates substantially the same elements as FIG. 5, and thus, the illustration thereof is omitted.

Referring to FIGS. 11 to 13 in conjunction with FIG. 5, a light emitting display device 100 according to another embodiment of the present disclosure may further include a bridge pattern BP which connects at least one dummy electrode DE with an auxiliary power line EVSS.

The at least one dummy electrode DE according to another embodiment of the present disclosure may be electrically connected with the auxiliary power line EVSS through the bridge pattern BP.

The bridge pattern BP may be disposed on an interlayer insulation layer ILD. The bridge pattern BP may be disposed to overlap an auxiliary power line EVSS. The bridge pattern BP may overlap a portion where the auxiliary power line EVSS is not divided into a first portion EVSS_d1 and a second portion EVSS_d2 and is provided as one body. For example, the bridge pattern BP may include a first bridge pattern BP1 and a second bridge pattern BP2 which are respectively disposed at one end and the other end of the auxiliary power line EVSS with a separation space, which is between a first portion EVSS_d1 and a second portion EVSS_d2 of the auxiliary power line EVSS, therebetween. The bridge pattern BP may be formed of the same material on the same layer as source/drain electrodes SD1 and SD2 of a TFT TR. Also, the bridge pattern BP may be formed of the same material as that of the auxiliary power electrode AXE, on a layer which differs from the auxiliary power electrode AXE. For example, the bridge pattern BP may be formed simultaneously through the same process on a layer which differs from the source/drain electrodes SD1 and SD2. For example, the bridge pattern BP may be formed simultaneously through the same process on a layer which differs from the auxiliary power electrode AXE.

At least a portion of the bridge pattern BP may overlap the at least one dummy electrode DE. For example, the first bridge pattern BP1 may overlap the first dummy electrode DE1, and the second bridge pattern BP2 may overlap the second dummy electrode DE2.

The first bridge pattern BP1 may be disposed to overlap one end of the auxiliary power line EVSS. One end of the first bridge pattern BP1 may overlap the auxiliary power line EVSS, and the other end of the first bridge pattern BP1 may overlap the first dummy electrode DE1. For example, the one end of the first bridge pattern BP1 may directly overlap the auxiliary power line EVSS, and the other end of the first bridge pattern BP1 may overlap the auxiliary power line EVSS with the first dummy electrode DE1 therebetween. The one end of the first bridge pattern BP1 may contact and be electrically connected with the auxiliary power line EVSS through a ninth contact hole CH9 passing through the interlayer insulation layer ILD and the buffer layer BUF. Also, the other end of the first bridge pattern BP1 may contact and be electrically connected with the first dummy electrode DE1 through an eleventh contact hole CH11 passing through the interlayer insulation layer ILD. The first bridge pattern BP1 may electrically connect the auxiliary power line EVSS with the first dummy electrode DE1.

The second bridge pattern BP2 may be disposed to overlap the other end of the auxiliary power line EVSS. One end of the second bridge pattern BP2 may overlap the auxiliary power line EVSS, and the other end of the second bridge pattern BP2 may overlap the second dummy electrode DE2. For example, the one end of the second bridge pattern BP2 may directly overlap the auxiliary power line EVSS, and the other end of the second bridge pattern BP2 may overlap the auxiliary power line EVSS with the second dummy electrode DE2 therebetween. The one end of the second bridge pattern BP2 may contact and be electrically connected with the auxiliary power line EVSS through a tenth contact hole CH10 passing through the interlayer insulation layer ILD and the buffer layer BUF. Also, the other end of the second bridge pattern BP2 may contact and be electrically connected with the second dummy electrode DE2 through a twelfth contact hole CH12 passing through the interlayer insulation layer ILD. The second bridge pattern BP2 may electrically connect the auxiliary power line EVSS with the second dummy electrode DE2.

Referring to FIG. 12, the at least one dummy electrode DE according to another embodiment of the present disclosure may be electrically connected with the auxiliary power line EVSS and the bridge pattern BP.

The at least one dummy electrode DE may contact and be electrically connected with the auxiliary power line EVSS through the contact holes CH7 and CH8 passing through the buffer layer BUF and a gate insulation layer GI and may contact and be electrically connected with the bridge pattern BP through the contact holes CH11 and CH12 passing through an interlayer insulation layer ILD.

Referring to FIG. 13, the at least one dummy electrode DE according to another embodiment of the present disclosure may be electrically connected with the auxiliary power line EVSS through the bridge pattern BP.

The at least one dummy electrode DE may contact and be electrically connected with the bridge pattern BP through the contact holes CH11 and CH12 passing through the interlayer insulation layer ILD and may be electrically connected with the auxiliary power line EVSS through the bridge pattern BP.

According to another embodiment of the present disclosure, the at least one dummy electrode DE may pass through the bridge pattern BP, or may be directly and electrically connected with the auxiliary power line EVSS and may not be electrically floated. Also, the at least one dummy electrode DE may pass through the bridge pattern BP, or may be directly supplied with an auxiliary power (or a low level voltage) through the auxiliary power line EVSS. A repair pattern RP based on laser welding on the at least one dummy electrode DE may electrically contact a common electrode CE and may directly supply the auxiliary power, and thus, a contact defect of the common electrode CE may be more effectively repaired. Also, the at least one dummy electrode DE may be electrically connected with the auxiliary power line EVSS through the bridge pattern BP and may be directly and electrically connected with the auxiliary power line EVSS, and thus, the supply of the auxiliary power (or the low level voltage) through the auxiliary power line EVSS may be more smoothly performed and a contact defect of the common electrode CE may be more effectively repaired.

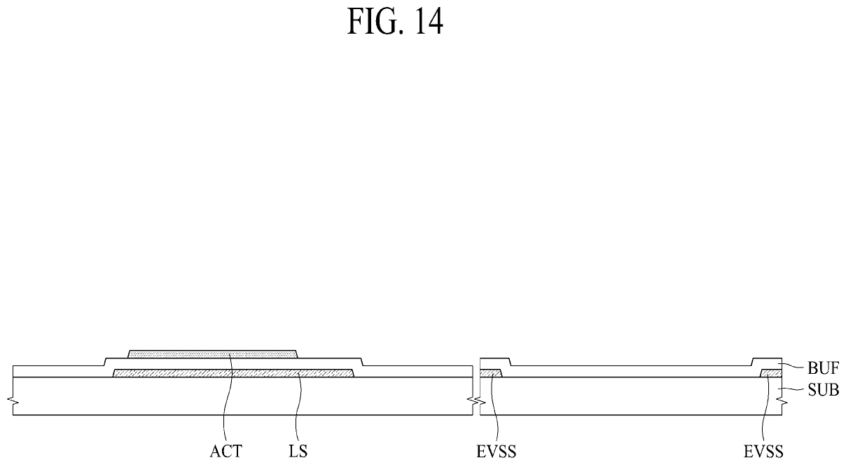

Hereinafter, a method of manufacturing a light emitting display device 100 according to an embodiment of the present disclosure will be described in more detail with reference to FIGS. 14 to 23.

FIGS. 14 to 23 are manufacturing process diagrams for describing a method of manufacturing a light emitting display device 100 according to an embodiment of the present disclosure. In FIGS. 14 to 23, in a structure of a contact portion CA of the light emitting display device 100, a structure of the contact portion CA illustrated in FIG. 6 has been mainly described, but the light emitting display device 100 may be manufactured in a structure of the contact portion CA illustrated in FIGS. 10, 12, and 13.

Referring to FIG. 14, a light blocking layer LS and an auxiliary power line EVSS may be formed on a substrate SUB. The light blocking layer LS and the auxiliary power line EVSS may include the same material and may be formed simultaneously through the same process. A buffer layer BUF may be formed on the light blocking layer LS and the auxiliary power line EVSS. The buffer layer BUF may be formed all over the substrate SUB.

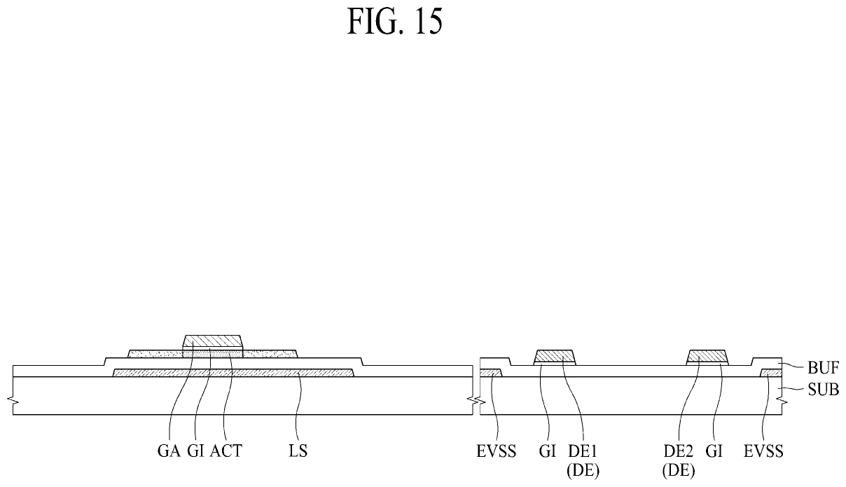

Referring to FIG. 15, an active layer ACT of a TFT TR may be formed on the buffer layer BUF. A gate insulation layer GI may be formed on the active layer ACT. A gate electrode GA of the TFT TR may be formed on the gate insulation layer GI. Also, at least one dummy electrode DE may be formed on the buffer layer BUF. The at least one dummy electrode DE may be formed on the buffer layer BUF with the gate insulation layer GI therebetween. Alternatively, the at least one dummy electrode DE may be formed on the buffer layer BUF with the gate insulation layer GI and the active layer ACT therebetween. The gate electrode GA and the at least one dummy electrode DE may include the same material and may be formed simultaneously through the same process. The gate insulation layer GI may be patterned along with the at least one dummy electrode DE and the gate electrode GA and may be disposed under each of the at least one dummy electrode DE and the gate electrode GA.

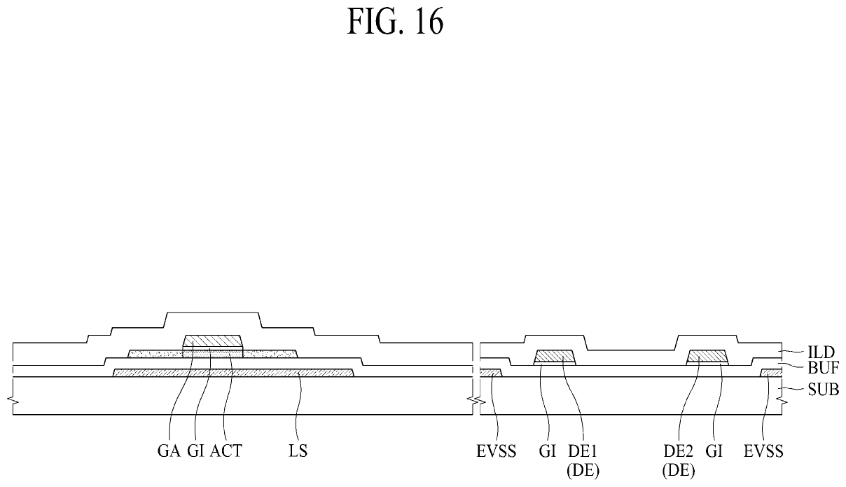

Referring to FIG. 16, an interlayer insulation layer ILD may be formed on the buffer layer BUF on which the active layer ACT and the gate electrode GA of the TFT TR and the at least one dummy electrode DE are formed. The interlayer insulation layer ILD may be formed to cover the gate electrode GA and the at least one dummy electrode DE.

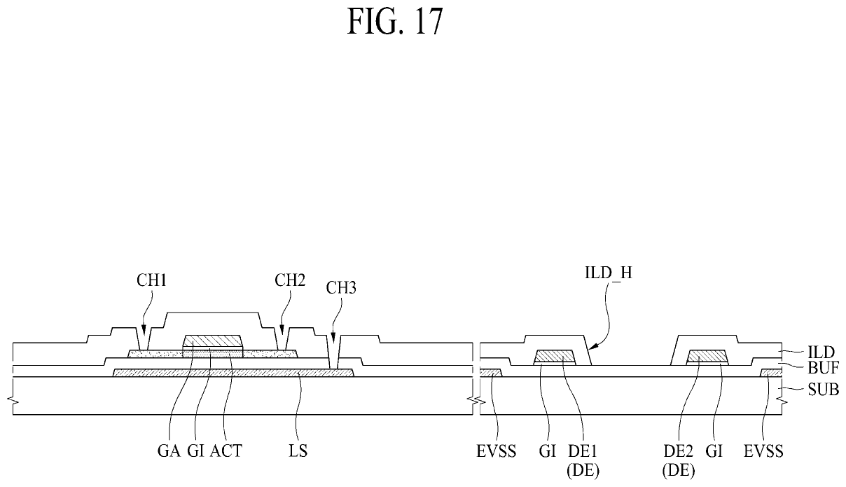

Referring to FIG. 17, a plurality of contact holes CH1 to CH3 may be formed in the interlayer insulation layer ILD. Also, by removing at least a portion of the interlayer insulation layer ILD, an opening portion ILD_H may be formed in the interlayer insulation layer ILD. An upper surface of the buffer layer BUF may be exposed through the opening portion ILD_H of the interlayer insulation layer ILD. The plurality of contact holes CH1 to CH3 and the opening portion ILD_H passing through the interlayer insulation layer ILD may be simultaneously formed by using the same mask. A first contact hole CH1 of the interlayer insulation layer ILD may connect the active layer ACT of the TFT TR with a first source/drain electrode SD1 of the TFT TR, a second contact hole CH2 may connect the active layer ACT of the TFT TR with a second source/drain electrode SD2 of the TFT TR, and a third contact hole CH3 may connect a light blocking layer LS with a second source/drain electrode SD2 of the TFT TR. For example, the third contact hole CH3 may be formed to pass through the interlayer insulation layer ILD and the buffer layer BUF. Also, the opening portion ILD_H of the interlayer insulation layer ILD may expose the upper surface of the buffer layer BUF, and then, an auxiliary power electrode AXE may be disposed.

According to another embodiment of the present disclosure, the at least one dummy electrode DE may be electrically connected with an auxiliary power line EVSS with the buffer layer BUF therebetween, or may be electrically connected with a bridge pattern BP with the interlayer insulation layer ILD therebetween. In this case, a portion of the at least one dummy electrode DE may be formed to overlap the auxiliary power line EVSS. Alternatively, contact holes CH7 and CH8 which pass through the at least one dummy electrode DE and the auxiliary power line EVSS to be connected therebetween may be formed in the buffer layer BUF. Alternatively, contact holes CH11 and CH12 which pass through the at least one dummy electrode DE and the bridge pattern BP to be connected therebetween may be formed in the interlayer insulation layer ILD.

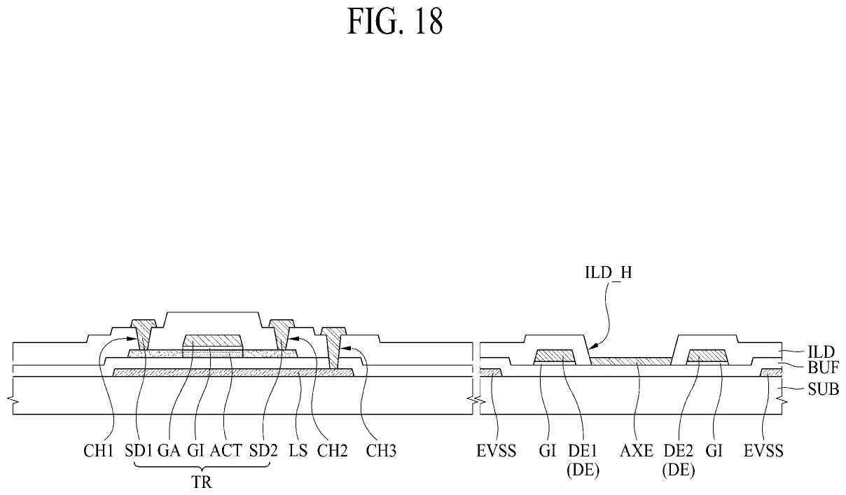

Referring to FIG. 18, the first source/drain electrode SD1 and the second source/drain electrode SD2 of the TFT TR and the auxiliary power electrode AXE may be formed on the interlayer insulation layer ILD. The first source/drain electrode SD1 may contact the active layer ACT through the first contact hole CH1 of the interlayer insulation layer ILD. The second source/drain electrode SD2 may contact the active layer ACT through the second contact hole CH2 of the interlayer insulation layer ILD and may contact the light blocking layer LS through the third contact hole CH3 of the interlayer insulation layer ILD and the buffer layer BUF. Also, the auxiliary power electrode AXE may be formed on the buffer layer BUF. For example, the auxiliary power electrode AXE may be formed in the opening portion ILD_H which is formed by at least a portion of the interlayer insulation layer ILD. The auxiliary power electrode AXE may be formed on the buffer layer BUF through the opening portion ILD_H of the interlayer insulation layer ILD. The auxiliary power electrode AXE may be formed to have a height which is lower than at least one adjacent dummy electrode DE. The first source/drain electrode SD1 and the second source/drain electrode SD2 may include the same material as that of the auxiliary power electrode AXE and may be formed simultaneously through the same process.

According to another embodiment of the present disclosure, the light emitting display device 100 may further include the bridge pattern BP which connects the at least one dummy electrode DE with the auxiliary power line EVSS. In this case, the bridge pattern BP may be formed on the interlayer insulation layer ILD. The bridge pattern BP may be formed to overlap the auxiliary power line EVSS and the at least one dummy electrode DE. Also, contact holes CH9 and CH10 which pass through the bridge pattern BP and the auxiliary power line EVSS to be connected therebetween may be formed in the buffer layer BUF. Also, contact holes CH11 and CH12 which pass through the bridge pattern BP and the at least one dummy electrode DE to be connected therebetween may be formed in the interlayer insulation layer ILD.

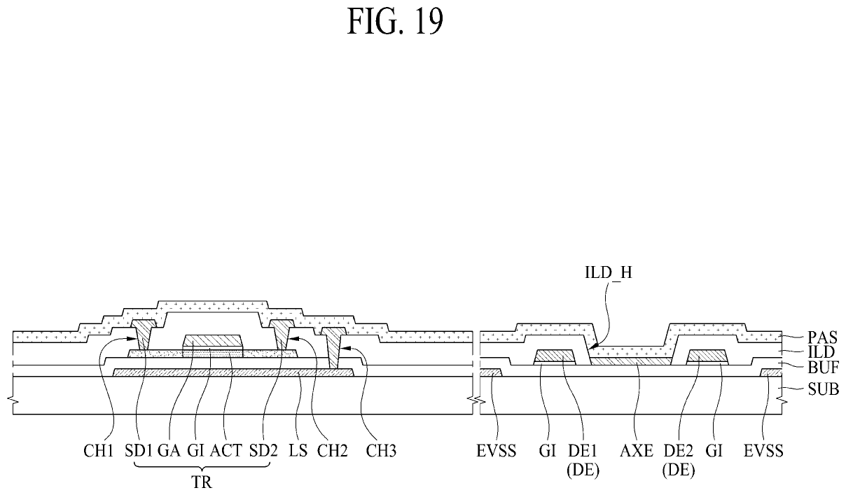

Referring to FIG. 19, a passivation layer PAS may be formed all over the substrate SUB. The passivation layer PAS may be formed on the interlayer insulation layer ILD. The passivation layer PAS may be formed to cover the first source/drain electrode SD1 and the second source/drain electrode SD2 of the TFT TR and the auxiliary power electrode AXE.

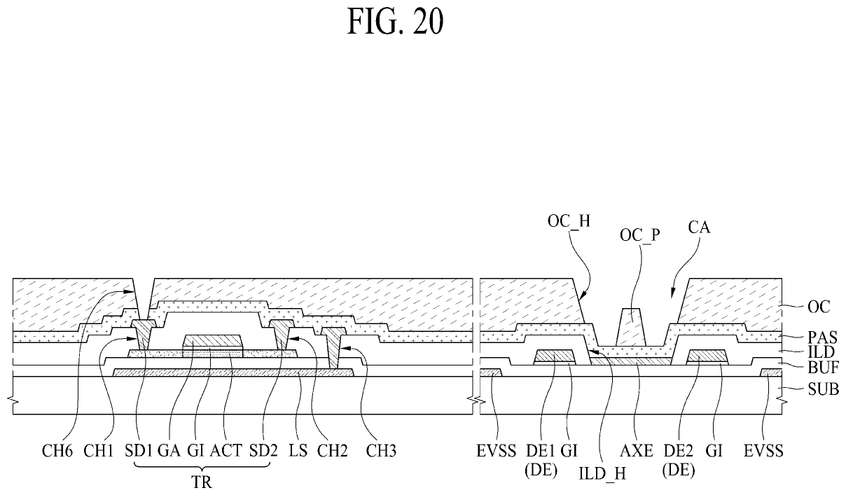

Referring to FIG. 20, an overcoat layer OC may be formed on the passivation layer PAS. A sixth contact hole CH6 exposing the first source/drain electrode SD1 may be formed in the overcoat layer OC. The sixth contact hole CH6 of the overcoat layer OC may connect the first source/drain electrode SD1 of the TFT TR with a pixel electrode PXL. Also, the overcoat layer OC may be patterned to expose at least a portion of the passivation layer PAS overlapping the auxiliary power electrode AXE.

The overcoat layer OC may include a second opening portion OC_H which exposes a portion of the passivation layer PAS, and a second pattern OC_P configuring an undercut structure UC may be patterned at a center portion of the second opening portion OC_H. The second opening portion OC_H may be patterned to have an island pattern at a center of an exposure region of the passivation layer PAS. The passivation layer PAS may be exposed between the second pattern OC_P and the second opening portion OC_H. Through a subsequent process, the passivation layer PAS between the second pattern OC_P and the second opening portion OC_H, and a portion of the auxiliary power electrode AXE may be exposed through a portion from which the passivation layer PAS is removed.

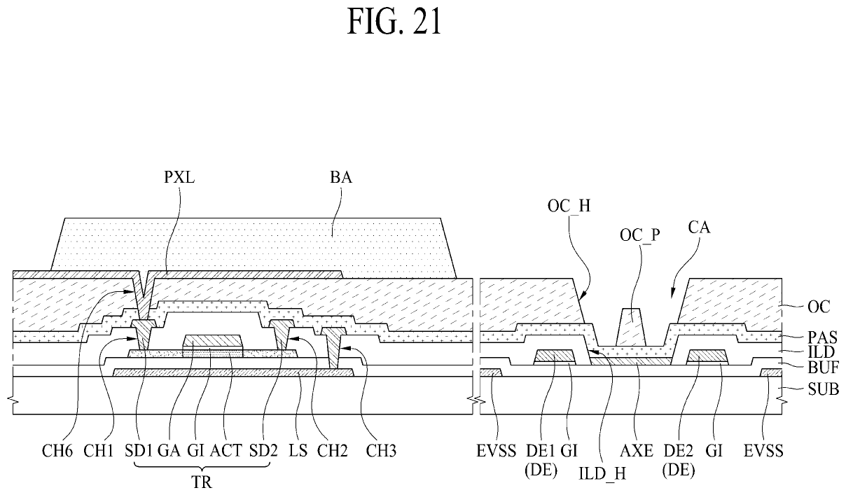

Referring to FIG. 21, the pixel electrode PXL may be formed on the overcoat layer OC. The pixel electrode PXL may contact the first source/drain electrode SD1 of the TFT TR through the sixth contact hole CH6 of the overcoat layer OC. A bank layer BA may be formed on the overcoat layer OC and the pixel electrode PXL. The bank layer BA may be formed to cover an edge of the pixel electrode PXL.

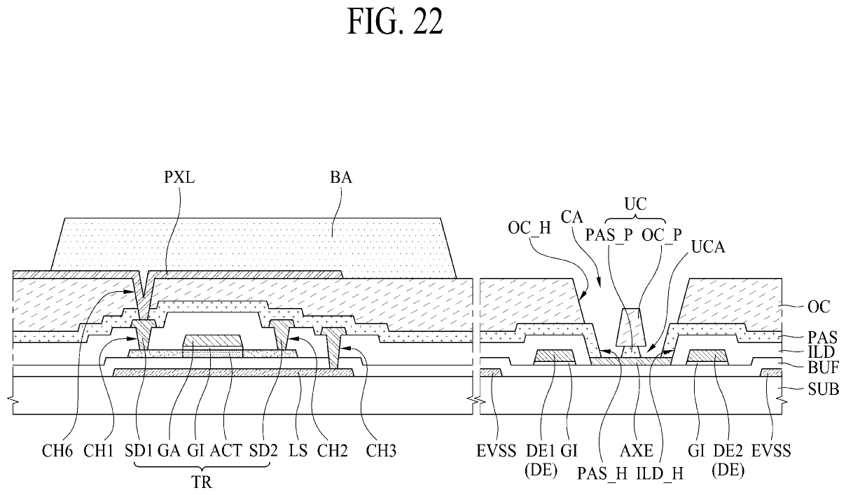

Referring to FIG. 22, a photoresist may be formed on the overcoat layer OC. The photoresist may be patterned to cover the second opening portion OC_H and an upper surface of the overcoat layer OC at a periphery of the second pattern OC_P. The photoresist may not be disposed on the second pattern OC_P. The photoresist may be formed so that the passivation layer PAS is exposed at the periphery of the second pattern OC_P. The second pattern OC_P may function as a mask pattern of the passivation layer PAS along with the photoresist. A portion of the passivation layer PAS may be removed by performing a wet etching process which uses the second pattern OC_P and the photoresist as a mask pattern.

The passivation layer PAS may be patterned to include a first opening portion PAS_H having a size which is less than that of the second opening portion OC_H of the overcoat layer OC, based on a wet etching process, and a first pattern PAS_P configuring the undercut structure UC may be patterned under the second pattern OC_P. The first pattern PAS_P of the passivation layer PAS may be formed by additionally removing a portion of the passivation layer PAS disposed under an edge of the photoresist. For example, the first pattern PAS_P may be formed by additionally removing a portion of the passivation layer PAS, disposed under the edge of the photoresist, in a direction toward an inner portion instead of an end of the photoresist. Also, the first pattern PAS_P of the passivation layer PAS may be formed by additionally removing a portion of the passivation layer PAS disposed under an edge of the second pattern OC_P. For example, the first pattern PAS_P may be formed by additionally removing a portion of the passivation layer PAS, disposed under the edge of the second pattern OC_P, in a direction toward an inner portion from an end of the second pattern OC_P. The first pattern PAS_P may be formed to protrude more inward than the edge of the second pattern OC_P, and thus, an undercut region UCA may be formed.

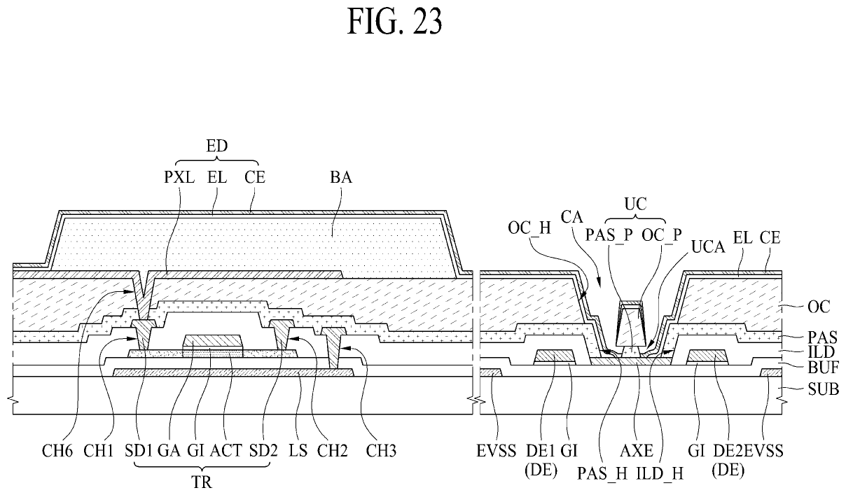

Referring to FIG. 23, after the bank layer BA is formed and the first opening portion PAS_H of the passivation layer PAS and the undercut structure UC is formed, an emission layer EL and a common electrode CE may be formed. The emission layer EL may be formed on the pixel electrode PXL and the bank layer BA and may be disconnected without being formed in the undercut region UCA. The common electrode CE may be formed on the emission layer EL. The common electrode CE may be formed on the auxiliary power electrode AXE exposed by the emission layer EL, in the undercut region UCA. The common electrode CE may directly contact and be electrically connected with the auxiliary power electrode AXE.

According to an embodiment of the present disclosure, after manufacturing of the light emitting display device 100 is completed, when a contact defect occurs between the auxiliary power electrode AXE and the common electrode CE, a repair process for recovering an electrical connection between the auxiliary power electrode AXE and the common electrode CE may be performed.

The at least one dummy electrode DE according to an embodiment of the present disclosure may be a welding region onto which a laser beam is irradiated, in a repair process. In the repair process, the laser beam may not be directly irradiated onto the auxiliary power electrode AXE and may be irradiated onto the at least one dummy electrode DE disposed at a periphery of the auxiliary power electrode AXE, and thus, laser welding may be performed on the at least one dummy electrode DE, thereby preventing or at least reducing the damage of an undercut structure UC on the auxiliary power electrode AXE and smoothly recovering the electrical connection between the auxiliary power electrode AXE and the common electrode CE through a modified repair pattern RP of the at least one dummy electrode DE.

According to an embodiment of the present disclosure, the auxiliary power electrode AXE may have a thickness which is less than that of at least one dummy electrode DE or may have a height which is lower than that of the at least one dummy electrode DE from an upper surface of the substrate SUB, or an edge end thereof adjacent to the at least one dummy electrode DE may have a reverse tapered shape. A repair pattern based on laser welding on the at least one dummy electrode DE may more smoothly contact the auxiliary power electrode AXE, and thus, welding may be more smoothly performed and the electrical connection between the auxiliary power electrode AXE and the common electrode CE may be more smoothly recovered.

The light emitting display device according to the embodiment of the present disclosure may be described as follows.

The light emitting display device according to an embodiment of the present disclosure may include a substrate, an auxiliary power electrode disposed on the substrate, at least one dummy electrode disposed at a periphery of the auxiliary power electrode on the substrate, at least one protection layer covering the auxiliary power electrode and the at least one dummy electrode, and a contact portion passing through the at least one protection layer to expose a portion of the auxiliary power electrode, the at least one dummy electrode may be electrically floating, or may be supplied with a same voltage as a voltage applied to the auxiliary power electrode.

In the light emitting display device according to an embodiment of the present disclosure, the auxiliary power electrode may have a thickness which differs from a thickness of the at least one dummy electrode.

In the light emitting display device according to an embodiment of the present disclosure, the at least one dummy electrode may be disposed at at least one of one side and the other side of the auxiliary power electrode.

In the light emitting display device according to an embodiment of the present disclosure, the at least one dummy electrode may be electrically connected with the auxiliary power electrode by laser welding, in the contact portion.

In the light emitting display device according to an embodiment of the present disclosure, the auxiliary power electrode and the at least one dummy electrode may be disposed on different layers.

In the light emitting display device according to an embodiment of the present disclosure, may further include at least one insulation layer between the substrate and the at least one protection layer, the at least one insulation layer may include a first insulation layer on the substrate, the first insulation layer including an upper surface where the auxiliary power electrode is disposed, a second insulation layer disposed on the first insulation layer to overlap the at least one dummy electrode, and a third insulation layer covering the at least one dummy electrode.

In the light emitting display device according to an embodiment of the present disclosure, the auxiliary power electrode may be disposed on the first insulation layer in a hole in the third insulation layer.

In the light emitting display device according to an embodiment of the present disclosure, the auxiliary power electrode may be apart from the at least one dummy electrode with the third insulation layer therebetween.

In the light emitting display device according to an embodiment of the present disclosure, may further include an auxiliary power line disposed on the substrate and connected with the auxiliary power electrode, with the at least one insulation layer between the auxiliary power line and the auxiliary power electrode, at least a portion of the auxiliary power electrode may overlap the auxiliary power line.

In the light emitting display device according to an embodiment of the present disclosure, the auxiliary power line may extend in a first direction, and at least a portion of the auxiliary power line may include a first portion and a second portion which are divided to be apart from each other in a second direction intersecting with the first direction, and a separation space between the first portion and the second portion of the auxiliary power line may overlap the auxiliary power electrode and at least a portion of the at least one dummy electrode.

In the light emitting display device according to an embodiment of the present disclosure, the auxiliary power electrode may overlap the first portion and the second portion of the auxiliary power line and may be connected with the auxiliary power line through a contact hole passing through the at least one insulation layer overlapping the first portion and the second portion of the auxiliary power line.

In the light emitting display device according to an embodiment of the present disclosure, the contact portion may overlap the separation space, and a portion, overlapping the separation space, of the at least one dummy electrode may be electrically connected with the auxiliary power electrode by laser welding, in the contact portion.

In the light emitting display device according to an embodiment of the present disclosure, the at least one dummy electrode may be not connected with the auxiliary power line with the at least one insulation layer therebetween.

In the light emitting display device according to an embodiment of the present disclosure, at least a portion of the at least one dummy electrode may overlap the auxiliary power line, and the at least one dummy electrode may be connected with the auxiliary power line through a contact hole passing through the at least one insulation layer overlapping the auxiliary power line.

In the light emitting display device according to an embodiment of the present disclosure, may further include a bridge pattern connected between the auxiliary power line and the at least one dummy electrode, the bridge pattern may include the same material as a material of the auxiliary power electrode.

In the light emitting display device according to an embodiment of the present disclosure, one end of the bridge pattern may overlap the auxiliary power line and may be connected with the auxiliary power line through a first contact hole passing through the at least one insulation layer between the bridge pattern and the auxiliary power line, and the other end of the bridge pattern may overlap the at least one dummy electrode and may be connected with the at least one dummy electrode through a second contact hole passing through the at least one insulation layer between the bridge pattern and the at least one dummy electrode.

In the light emitting display device according to an embodiment of the present disclosure, may further include an undercut structure including the same material as a material of the at least one protection layer and including an undercut region, the undercut structure being disposed on a portion of the auxiliary power electrode in the contact portion.

In the light emitting display device according to an embodiment of the present disclosure, the at least one protection layer may include a first protection layer on the auxiliary power electrode, the first protection layer including an inorganic insulating material, and a second protection layer on the first protection layer, the second protection layer including an organic insulating material.

In the light emitting display device according to an embodiment of the present disclosure, the undercut structure may include a first pattern on a portion of the auxiliary power electrode, the first pattern including the same material as a material of the first protection layer, and a second pattern disposed on the first pattern to protrude from the first pattern, the second pattern including the same material as a material of the second protection layer, and the undercut region may be provided under the second pattern protruding from a lateral surface of the first pattern.

In the light emitting display device according to an embodiment of the present disclosure, may further include a thin film transistor disposed on the substrate, a pixel electrode disposed on the at least one protection layer and connected with the thin film transistor, an emission layer on the pixel electrode, and a common electrode on the emission layer, the common electrode may directly contact the auxiliary power electrode, in the undercut region.

In the light emitting display device according to an embodiment of the present disclosure, may further include a thin film transistor disposed on the substrate, a pixel electrode disposed on the at least one protection layer and connected with the thin film transistor, an emission layer on the pixel electrode, and a common electrode on the emission layer, the common electrode may be in electrical contact with the auxiliary power electrode.

In the light emitting display device according to an embodiment of the present disclosure, the at least one dummy electrode may be electrically connected with the common electrode by laser welding, in the contact portion.

In the light emitting display device according to an embodiment of the present disclosure, the voltage applied to the auxiliary power electrode may be a low level or common voltage.

In the light emitting display device according to an embodiment of the present disclosure, the common electrode may be configured to receive the low level or common voltage.

It will be apparent to those skilled in the art that the present disclosure described above is not limited by the above-described embodiments and the accompanying drawings and that various substitutions, modifications, and variations can be made in the present disclosure without departing from the spirit or scope of the disclosures. Consequently, the scope of the present disclosure is defined by the accompanying claims, and it is intended that all variations or modifications derived from the meaning, scope, and equivalent concept of the claims fall within the scope of the present disclosure.

What is claimed is:

1. A light emitting display device comprising:
a substrate;
an auxiliary power electrode disposed on the substrate;
at least one dummy electrode disposed at a periphery of the auxiliary power electrode on the substrate;
at least one protection layer covering the auxiliary power electrode and the at least one dummy electrode; and
a contact portion passing through the at least one protection layer to expose a portion of the auxiliary power electrode,
wherein the at least one dummy electrode is electrically floating, or is supplied with a same voltage as a voltage applied to the auxiliary power electrode.

2. The light emitting display device of claim 1, wherein the auxiliary power electrode has a thickness which differs from a thickness of the at least one dummy electrode.

3. The light emitting display device of claim 1, wherein the at least one dummy electrode is disposed at at least one of a first side or a second side of the auxiliary power electrode.

4. The light emitting display device of claim 1, wherein the at least one dummy electrode is electrically connected with the auxiliary power electrode by laser welding, in the contact portion.

5. The light emitting display device of claim 1, wherein the auxiliary power electrode and the at least one dummy electrode are disposed on different layers.

6. The light emitting display device of claim 1, further comprising at least one insulation layer between the substrate and the at least one protection layer,
wherein the at least one insulation layer comprises:
a first insulation layer on the substrate, the first insulation layer including an upper surface where the auxiliary power electrode is disposed;
a second insulation layer disposed on the first insulation layer, the second insulation layer overlapping the at least one dummy electrode; and
a third insulation layer covering the at least one dummy electrode.

7. The light emitting display device of claim 6, wherein the auxiliary power electrode is disposed on the first insulation layer in a hole in the third insulation layer.

8. The light emitting display device of claim 7, wherein the auxiliary power electrode is apart from the at least one dummy electrode with the third insulation layer between the auxiliary power electrode and the at least one dummy electrode.

9. The light emitting display device of claim 6, further comprising an auxiliary power line disposed on the substrate and connected to the auxiliary power electrode, with the at least one insulation layer between the auxiliary power line and the auxiliary power electrode,
wherein at least a portion of the auxiliary power electrode overlaps the auxiliary power line.

10. The light emitting display device of claim 9, wherein the auxiliary power line extends in a first direction, and at least a portion of the auxiliary power line comprises a first portion and a second portion which are divided to be apart from each other in a second direction intersecting with the first direction, and
a separation space between the first portion and the second portion of the auxiliary power line overlaps the auxiliary power electrode and at least a portion of the at least one dummy electrode.

11. The light emitting display device of claim 10, wherein the auxiliary power electrode overlaps the first portion and the second portion of the auxiliary power line and is connected to the auxiliary power line through a contact hole passing through the at least one insulation layer overlapping the first portion and the second portion of the auxiliary power line.

12. The light emitting display device of claim 10, wherein the contact portion overlaps the separation space, and
a portion of the at least one dummy electrode that overlaps the separation space is electrically connected to the auxiliary power electrode by laser welding, in the contact portion.

13. The light emitting display device of claim 9, wherein the at least one dummy electrode is not connected to the auxiliary power line with the at least one insulation layer between the at least one dummy electrode and the auxiliary power line.

14. The light emitting display device of claim 9, wherein at least a portion of the at least one dummy electrode overlaps the auxiliary power line, and
the at least one dummy electrode is connected to the auxiliary power line through a contact hole passing through the at least one insulation layer overlapping the auxiliary power line.

15. The light emitting display device of claim 9, further comprising a bridge pattern between the auxiliary power line and the at least one dummy electrode,
wherein the bridge pattern comprises a same material as a material of the auxiliary power electrode.

16. The light emitting display device of claim 15, wherein a first end of the bridge pattern overlaps the auxiliary power line and is connected with the auxiliary power line through a first contact hole passing through the at least one insulation layer between the bridge pattern and the auxiliary power line, and
a second end of the bridge pattern overlaps the at least one dummy electrode and is connected to the at least one dummy electrode through a second contact hole passing through the at least one insulation layer between the bridge pattern and the at least one dummy electrode.

17. The light emitting display device of claim 1, further comprising an undercut structure including a same material as a material of the at least one protection layer and including an undercut region, the undercut structure being disposed on a portion of the auxiliary power electrode in the contact portion.

18. The light emitting display device of claim 17, wherein the at least one protection layer comprises:
a first protection layer on the auxiliary power electrode, the first protection layer including an inorganic insulating material; and
a second protection layer on the first protection layer, the second protection layer including an organic insulating material.

19. The light emitting display device of claim 18, wherein the undercut structure comprises:
a first pattern on a portion of the auxiliary power electrode, the first pattern including a same material as a material of the first protection layer; and
a second pattern disposed on the first pattern to protrude from the first pattern, the second pattern including a same material as a material of the second protection layer, and
the undercut region is provided under the second pattern protruding from a lateral surface of the first pattern.

20. The light emitting display device of claim 17, further comprising:
a thin film transistor disposed on the substrate;
a pixel electrode disposed on the at least one protection layer and connected to the thin film transistor;
an emission layer on the pixel electrode; and
a common electrode on the emission layer,
wherein the common electrode directly contacts the auxiliary power electrode in the undercut region.

21. The light emitting display device of claim 1, further comprising:
a thin film transistor disposed on the substrate;
a pixel electrode disposed on the at least one protection layer and connected with the thin film transistor;
an emission layer on the pixel electrode; and
a common electrode on the emission layer,
wherein the common electrode is in electrical contact with the auxiliary power electrode.

22. The light emitting display device of claim 21, wherein the at least one dummy electrode is electrically connected with the common electrode by laser welding in the contact portion.

23. The light emitting display device of claim 21, wherein the voltage applied to the auxiliary power electrode is a low level voltage or a common voltage.

24. The light emitting display device of claim 23, wherein the common electrode is configured to receive the low level voltage or the common voltage.
